(19) United States
(12) Patent Application Publication
(10) Pub. No.: US 2026/0122871 A1
(43) Pub. Date: Apr. 30, 2026

(54) ELECTROMAGNETIC WAVE SHIELDING MATERIAL, ELECTRONIC COMPONENT, AND ELECTRONIC APPARATUS

(71) Applicant: FUJIFILM Corporation, Tokyo (JP)

(72) Inventor: Kiyotaka FUKAGAWA, Minamiashigara-shi (JP)

(73) Assignee: FUJIFILM Corporation, Tokyo (JP)

(21) Appl. No.: 19/429,447

(22) Filed: Dec. 22, 2025

Related U.S. Application Data
(63) Continuation of application No. PCT/JP2024/021517, filed on Jun. 13, 2024.

(30) Foreign Application Priority Data
Jun. 26, 2023 (JP) 2023-104090
Sep. 11, 2023 (JP) 2023-146812

(51) Int. Cl. H05K 9/00; H01F 1/42

(52) U.S. Cl. CPC H05K 9/0088; H01F 1/42

(57) ABSTRACT

Provided are an electromagnetic wave shielding material including: a magnetic layer containing magnetic particles and an acrylic resin, provided between two metal layers, in which a cross-linking degree of the magnetic layer is 20% or more, and a glass transition temperature Tg of the magnetic layer is −80° C. or higher, and an electronic component and an electronic apparatus which include the electromagnetic wave shielding material.

### CROSS-REFERENCE TO RELATED APPLICATIONS

This application is a Continuation of PCT International Application No. PCT/JP2024/021517 filed on Jun. 13, 2024, which claims priority under 35 U.S.C. § 119(a) to Japanese Patent Application No. 2023-104090 filed on Jun. 26, 2023 and Japanese Patent Application No. 2023-146812 filed on Sep. 11, 2023. Each of the above applications is hereby expressly incorporated by reference, in its entirety, into the present application.

### BACKGROUND OF THE INVENTION

### 1. Field of the Invention

The present invention relates to an electromagnetic wave shielding material, an electronic component, and an electronic apparatus.

### 2. Description of the Related Art

JP2022-98300A discloses a resin composition containing a magnetic material. JP2022-98300A describes that a member produced using such a resin composition can be used as an electromagnetic wave shielding film (see paragraph 0243 of JP2022-98300A).

### SUMMARY OF THE INVENTION

In recent years, an electromagnetic wave shielding material has attracted attention as a material for reducing the influence of an electromagnetic wave in various electronic components and various electronic apparatuses. An electromagnetic wave shielding material is capable of exhibiting the performance of shielding electromagnetic waves (hereinafter, also referred to as an “electromagnetic wave shielding ability” or a “shielding ability”) by reflecting electromagnetic waves incident on the electromagnetic wave shielding material by the electromagnetic wave shielding material and/or by attenuating the electromagnetic waves inside the electromagnetic wave shielding material. For example, the member produced using the resin composition described in JP2022-98300A can function as an electromagnetic wave shielding material.

The electromagnetic wave shielding material can be exposed to a high temperature in a state of being incorporated into an electronic component or an electronic apparatus. Therefore, it is desired that the electromagnetic wave shielding material can exhibit a high shielding ability after being placed at a high temperature. The electromagnetic wave shielding material that exhibits a high shielding ability after being placed at a high temperature can contribute to a significant reduction in the influence of electromagnetic waves even after being placed at a high temperature in electronic components and electronic apparatuses. Hereinafter, the fact that a high shielding ability is exhibited after the electromagnetic wave shielding material is placed at a high temperature is also referred to as high heat resistance or excellent heat resistance.

In consideration of the above circumstances, an object of an aspect according to the present invention is to provide an electromagnetic wave shielding material having excellent heat resistance.

An aspect of the present invention is as follows.

[1] An electromagnetic wave shielding material comprising:
a magnetic layer containing magnetic particles and an acrylic resin, provided between two metal layers,
wherein a cross-linking degree of the magnetic layer is 20% or more, and
a glass transition temperature Tg of the magnetic layer is −80° C. or higher.

[2] The electromagnetic wave shielding material according to [1],
in which the glass transition temperature Tg of the magnetic layer is −80° C. or higher and lower than 5° C.

[3] The electromagnetic wave shielding material according to [1] or [2],
in which the magnetic layer contains a compound represented by Formula 1:

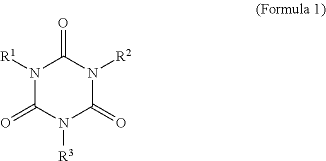

in Formula 1, R¹, R², and R³ each independently represent a hydrogen atom, an allyl group, an organic group including a hydroxy group, an organic group including a carboxy group, an organic group including an alkoxysilyl group, or a glycidyl group.

[4] The electromagnetic wave shielding material according to [3],
in which the glass transition temperature Tg of the magnetic layer is −80° C. or higher and lower than 5° C.

[5] The electromagnetic wave shielding material according to any one of [1] to [3],
in which the magnetic layer contains a compound represented by Formula 2:

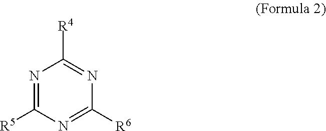

in Formula 2, R⁴, R⁵, and R⁶ each independently represent an amino group or an organic group including an alkoxysilyl group.

[6] The electromagnetic wave shielding material according to [5],
in which the glass transition temperature Tg of the magnetic layer is −80° C. or higher and lower than 5° C.

[7] The electromagnetic wave shielding material according to any one of [1] to [6],
in which the magnetic layer contains an acrylic resin having an alkyl (meth)acrylate structure in which the number of carbon atoms in an alkyl group is 2 or more and 8 or less.

[8] The electromagnetic wave shielding material according to any one of [1] to [7],
in which the magnetic layer contains an acrylic resin having an alkyl (meth)acrylate structure in which the number of carbon atoms in an alkyl group is 2 or more and 4 or less.

[9] The electromagnetic wave shielding material according to any one of [1] to [8],
in which the cross-linking degree of the magnetic layer is 20% or more and 98% or less.

[10] The electromagnetic wave shielding material according to any one of [1] to [9], further comprising:
one or more layers containing a resin, provided between the magnetic layer sandwiched between the two metal layers and one or both of the two metal layers.

[11] The electromagnetic wave shielding material according to any one of [1] to [10],
in which one or more of the metal layers are metal layers having an Al content of 80.0% by mass or more.

[12] The electromagnetic wave shielding material according to any one of [1] to [11],
in which the glass transition temperature Tg of the magnetic layer is −40° C. or higher and lower than −5° C.

[13] The electromagnetic wave shielding material according to any one of [1] to [12],
in which the magnetic layer contains an acrylic resin having an alkyl (meth)acrylate structure in which the number of carbon atoms in an alkyl group is 2 or more and 4 or less,
the cross-linking degree of the magnetic layer is 20% or more and 98% or less,
one or more of the metal layers are metal layers having an Al content of 80.0% by mass or more, and
the glass transition temperature Tg of the magnetic layer is −40° C. or higher and lower than −5° C.

[14] The electromagnetic wave shielding material according to [13], further comprising:
one or more layers containing a resin, provided between the magnetic layer sandwiched between the two metal layers and one or both of the two metal layers.

[15] The electromagnetic wave shielding material according to [13] or [14],
in which the magnetic layer contains a compound represented by Formula 1:

### (Formula 1)

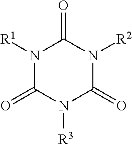

in Formula 1, R¹, R², and R³ each independently represent a hydrogen atom, an allyl group, an organic group including a hydroxy group, an organic group including a carboxy group, an organic group including an alkoxysilyl group, or a glycidyl group.

[16] The electromagnetic wave shielding material according to any one of [13] to [15],
in which the magnetic layer contains a compound represented by Formula 2:

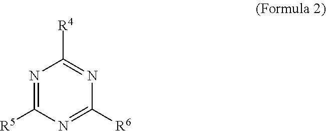

in Formula 2, R⁴, R⁵, and R⁶ each independently represent an amino group or an organic group including an alkoxysilyl group.

[17] An electronic component comprising:
the electromagnetic wave shielding material according to any one of [1] to [16].

[18] An electronic apparatus comprising:
the electromagnetic wave shielding material according to any one of [1] to [16].

According to one aspect of the present invention, it is possible to provide an electromagnetic wave shielding material having excellent heat resistance. In addition, according to one aspect of the present invention, it is possible to provide an electronic component and an electronic apparatus, which include the electromagnetic wave shielding material.

### BRIEF DESCRIPTION OF THE DRAWINGS

FIG. 1 is an explanatory view of a measurement of peel strength.

FIG. 2 is an explanatory view of the measurement of the peel strength.

### DESCRIPTION OF THE PREFERRED EMBODIMENTS

### [Electromagnetic Wave Shielding Material]

One aspect of the present invention relates to an electromagnetic wave shielding material including: a magnetic layer containing magnetic particles and an acrylic resin, provided between two metal layers, in which a cross-linking degree of the magnetic layer is 20% or more, and a glass transition temperature Tg of the magnetic layer is −80° C. or higher.

In the present invention and the present specification, the “electromagnetic wave shielding material” shall refer to a material that is capable of exhibiting shielding ability against an electromagnetic wave of at least one frequency or at least a part of a range of a frequency band. The “electromagnetic wave” includes a magnetic field wave and an electric field wave. The “electromagnetic wave shielding material” can be a material that is capable of exhibiting shielding ability against one or both of a magnetic field wave of at least one frequency or at least a part of a range of a frequency band and an electric field wave of at least one frequency or at least a part of a range of a frequency band.

In the present invention and the present specification, “magnetic” means having a ferromagnetic property. Details of the magnetic layer will be described later.

The electromagnetic wave shielding material includes a magnetic layer containing magnetic particles and an acrylic resin, provided between two metal layers. That is, the electromagnetic wave shielding material has a multilayer structure in which the magnetic layer is sandwiched between two metal layers. The inventors of the present invention speculate that the multilayer structure can contribute to the fact that the electromagnetic wave shielding material can exhibit a high shielding ability against an electromagnetic wave. The details are as follows.

In order to obtain a high shielding ability against electromagnetic waves in the electromagnetic wave shielding material, it is desirable to increase the reflection at the interface in addition to increasing the ability to attenuate electromagnetic waves. That is, it is desirable that the electromagnetic wave repeatedly reflects at the interface and passes through the electromagnetic wave shielding material a large number of times to be largely attenuated. However, as the behavior of the metal layer and the magnetic layer with respect to the electromagnetic wave, the reflection of the magnetic field wave at the interface tends to be small although the metal layer has a large ability to attenuate the electromagnetic wave, and the reflection of the magnetic field wave at the interface tends to be larger than that in the metal layer although the magnetic layer has a smaller ability to attenuate the electromagnetic wave than the metal layer. Therefore, with the metal layer alone or the magnetic layer alone, it is difficult to achieve both high reflection and high attenuation of, particularly, the magnetic field wave among the electromagnetic waves. On the other hand, due to having a multilayer structure in which the magnetic layer is sandwiched between two metal layers, the electromagnetic wave shielding material makes it possible to achieve both the above-described reflection at the interface and the above-described attenuation within the layer. The inventors of the present invention conceive that this is a reason why the electromagnetic wave shielding material is capable of exhibiting a high shielding ability against electromagnetic waves, specifically, against magnetic field waves.

Further, the magnetic layer included in the multilayer structure contains an acrylic resin. It is considered that the main chain of the acrylic resin is not easily thermally decomposed due to the carbon-carbon saturated bond in the main chain. The inventors of the present invention consider that containing of the acrylic resin in the magnetic layer can contribute to the fact that the electromagnetic wave shielding material can exhibit a high shielding ability without a significant reduction even after being placed at a high temperature.

In addition, the inventors of the present invention consider that the fact that the cross-linking degree of the magnetic layer is 20% or more and the fact that the glass transition temperature Tg of the magnetic layer is −80° C. or higher can also contribute to the fact that the electromagnetic wave shielding material can exhibit a high shielding ability without a significant reduction even after being placed at a high temperature.

Performance desired for the electromagnetic wave shielding material also includes excellent formability. The electromagnetic wave shielding material can be formed into various shapes in order to be incorporated into an electronic component or an electronic apparatus. The electromagnetic wave shielding material in which defects such as a shape defect and breakage are less likely to occur in forming can refer to the electromagnetic wave shielding material having excellent formability. An electromagnetic wave shielding material having excellent formability is desirable, from the viewpoint that, for example, a formed article is less likely to be broken in three-dimensional forming (in other words, forming in a three-dimensional manner). The glass transition temperature Tg of the magnetic layer is preferably lower than 5° C. The inventors of the present invention speculate that the fact that the glass transition temperature Tg of the magnetic layer is lower than 5° C. can contribute to the fact that the electromagnetic wave shielding material can exhibit excellent formability.

However, the present invention is not limited to the presumption described in the present specification.

Hereinafter, the electromagnetic wave shielding material will be described in more detail.

### <Magnetic Layer>

### (Cross-Linking Degree of Magnetic Layer)

In the present invention and the present specification, the cross-linking degree of the magnetic layer is a value obtained by the following method.

The proportion of the binder component of the magnetic layer is obtained by thermogravimetry/differential thermal analysis (TG/DTA). “TG/DTA” is generally called thermogravimetry/differential thermal analysis. Specifically, in the thermogravimetry/differential thermal analysis (TG/DTA) apparatus, a measurement specimen collected from the magnetic layer to be measured is measured under conditions of a measurement temperature range of 23° C. to 600° C. and a temperature rising rate of 10° C./min, and a mass reduction % at 600° C. is defined as a proportion (unit: % by mass) of the binder component.

A measurement specimen (70 mg) collected from the magnetic layer to be measured and 7 ml of tetrahydrofuran (THF) are added to a container in which the mass in a state of being empty is measured, and the entire measurement specimen is immersed in THF at room temperature for 12 hours. In the present invention and the present specification, the “room temperature” refers to 20° C. to 25° C.

Thereafter, the contents of the container are stirred for 30 minutes using a mix rotor at room temperature, and then the supernatant is removed in a state where THF-insoluble components in the container are attracted to the lower surface of the container with a magnet.

Thereafter, 7 ml of acetone is added to the container, the contents of the container are stirred for 30 minutes at room temperature using the mix rotor, and then the supernatant is removed in a state where acetone-insoluble components in the container are attracted to the lower surface of the container with the magnet.

Thereafter, the container is subjected to vacuum drying in a vacuum dryer having an internal atmospheric temperature of 80° C. for 1 hour, and then the mass of the container is measured. A value obtained by subtracting the mass of the empty container from the mass measured in this way is defined as the mass of the solvent-insoluble component.

The cross-linking degree is calculated from the following expression using the values of the mass of the solvent-insoluble component obtained in this way and the proportion of the binder component in the magnetic layer obtained by the TG/DTA measurement (unit: % by mass).

$$Cross - linking degree ( \% ) = [ 1 - \{ ( mass of measurement specimen ( 70 mg ) - mass of solvent - insoluble component ) / mass of binder component of measurement specimen \} ] \times 100$$

From the viewpoint of improving heat resistance of the electromagnetic wave shielding material, the cross-linking degree of the magnetic layer sandwiched between the two metal layers in the electromagnetic wave shielding material is 20% or more, preferably 30% or more, and more preferably 40% or more, 50% or more, and 60% or more in this order. The cross-linking degree can be, for example, 100% or less, less than 100%, 98% or less, 96% or less, 93% or less, or 90% or less.

### (Glass Transition Temperature Tg of Magnetic Layer)

The glass transition temperature Tg of the magnetic layer in the present invention and the present specification is determined as an intermediate temperature between a descent start point and a descent end point of a differential scanning calorimetry (DSC) chart from the measurement result of the heat flow measurement using a differential scanning calorimeter. Examples of the specific example of the measuring method include the methods described in the section of Examples described later.

From the viewpoint of improving heat resistance of the electromagnetic wave shielding material, the glass transition temperature of the magnetic layer sandwiched between the two metal layers in the electromagnetic wave shielding material is −80° C. or higher, preferably −70° C. or higher, and more preferably −60° C. or higher, −50° C. or higher, −40° C. or higher, −30° C. or higher, and −20° C. or higher in this order.

Meanwhile, from a viewpoint of improving the formability, the glass transition temperature of the magnetic layer sandwiched between the two metal layers in the electromagnetic wave shielding material is preferably lower than 5° C., more preferably 0° C. or lower, still more preferably −5° C. or lower, still more preferably lower than −5° C., and still more preferably −10° C. or lower.

### (Magnetic Particle)

The magnetic particles contained in the magnetic layer can be one kind selected from the group consisting of magnetic particles generally called soft magnetic particles, such as metal particles and ferrite particles, or can be also a combination of two or more kinds thereof. Since the metal particles generally have a saturation magnetic flux density of about 2 to 3 times as compared with ferrite particles, the metal particles can maintain specific magnetic permeability and exhibit shielding ability even under a strong magnetic field without magnetic saturation. Therefore, the magnetic particles to be contained in the magnetic layer are preferably metal particles. In the present invention and the present specification, a layer containing metal particles as the magnetic particles shall correspond to the “magnetic layer”.

### Metal Particle

Examples of the metal particles as the magnetic particles include particles of Sendust (a Fe—Si—Al alloy), permalloy (a Fe—Ni alloy), molybdenum permalloy (a Fe—Ni—Mo alloy), a Fe—Si alloy, a Fe—Cr alloy, a Fe-containing alloy generally called the iron-based amorphous alloy, a Co-containing alloys generally called the cobalt-based amorphous alloy, an alloy generally called the nanocrystal alloy, iron, Permendur (a Fe—Co alloy). Among them, Sendust is preferable since it exhibits a high saturation magnetic flux density and a high specific magnetic permeability. The metal particle may contain, in addition to the constitutional element of the metal (including the alloy), elements contained in an additive that can be optionally added and/or elements contained in impurities that can be unintentionally mixed in a manufacturing process of the metal particle at any content rate. In the metal particle, the content of the constitutional element of the metal (including the alloy) is preferably 90.0% by mass or more and more preferably 95.0% by mass or more, and it may be 100% by mass or may be less than 100% by mass, 99.9% by mass or less, or 99.0% by mass or less.

In one form, the shielding ability of the electromagnetic wave shielding material against the electromagnetic wave can be evaluated using, as an indicator, the magnetic permeability (specifically, the real part of the complex specific magnetic permeability) of the magnetic layer included in the electromagnetic wave shielding material. The electromagnetic wave shielding material including a magnetic layer exhibiting a high magnetic permeability (specifically, a real part of a complex specific magnetic permeability) is preferable since a high shielding ability can be exhibited against electromagnetic waves.

In a case where a complex specific magnetic permeability is measured by a magnetic permeability measuring apparatus, a real part μ′ and an imaginary part μ″ are generally displayed. In the present invention and the present specification, a real part of a complex specific magnetic permeability shall refer to such a real part μ′. Hereinafter, a real part of a complex specific magnetic permeability at a frequency of 3 megahertz (MHz) is also simply referred to as “magnetic permeability” or “magnetic permeability μ′”. The magnetic permeability can be measured by a commercially available magnetic permeability measuring apparatus or a magnetic permeability measuring apparatus having a known configuration. The measurement temperature is set to 25° C. By setting an atmospheric temperature around the measurement specimen to the measurement temperature, the temperature of the measurement specimen can be set to the measurement temperature by establishing a temperature equilibrium. From the viewpoint that still more excellent electromagnetic wave shielding ability can be exhibited, the magnetic permeability (the real part of complex specific magnetic permeability at a frequency of 3 MHz) of the magnetic layer included in the electromagnetic wave shielding material is preferably 40 or more, more preferably 100 or more in all values before and after thermal aging at 120° C., which are obtained by the method described in the column of Examples described later. In addition, the magnetic permeability can be, for example, 500 or less, 300 or less, or 200 or less, and it can exceed the values exemplified here. The electromagnetic wave shielding material having a high magnetic permeability is preferable since it can exhibit an excellent electromagnetic wave shielding ability.

From the viewpoint of forming a magnetic layer that exhibits a high magnetic permeability, the above-described magnetic particles are preferably particles having a flat shape (flat-shaped particles), and more preferably metal particles having a flat shape. In a case of arranging the long side direction of the flat-shaped particles to be closer to a state parallel to the in-plane direction of the magnetic layer, the magnetic layer can exhibit a higher magnetic permeability since the diamagnetic field can be reduced by aligning the long side direction of the particle with the vibration direction of the electromagnetic wave incident orthogonal to the electromagnetic wave shielding material. In the present invention and the present specification, the “flat-shaped particle” refers to a particle having an aspect ratio of 0.200 or less. The aspect ratio of the flat-shaped particles is preferably 0.150 or less, and more preferably 0.100 or less. The aspect ratio of the flat-shaped particles can be, for example, 0.010 or more, 0.020 or more, or 0.030 or more. It is possible to make the shape of the particle flat-shaped, for example, by carrying out the flattening process according to a known method. For the flattening process, for example, the description of JP2018-131640A can be referenced, specifically, the description of paragraphs 0016 and 0017 and the description of Examples of the same publication can be referenced. Examples of the magnetic layer that exhibits a high magnetic permeability include a magnetic layer containing flat-shaped particles of Sendust.

As described above, from the viewpoint of forming a layer that exhibits a high magnetic permeability as the magnetic layer, it is preferable to arrange the long side direction of the flat-shaped particles to be closer to a state parallel to the in-plane direction of the magnetic layer. From this point, the alignment degree which is a sum of an absolute value of the average value of alignment angles of the flat-shaped particles with respect to the surface of the magnetic layer and a variance of the alignment angles is preferably 300 or lower, more preferably 250 or lower, still more preferably 20° or lower, and even still more preferably 15° or lower. The alignment degree can be, for example, 3° or higher, 5° or higher, or 100 or higher, and it can be lower than the values exemplified here. A method of controlling the alignment degree will be described later.

In the present invention and the present specification, the aspect ratio of the magnetic particle and the alignment degree are determined according to the following methods.

A cross section of a magnetic layer is exposed according to a known method. In a randomly selected region of this cross section, a cross-sectional image is acquired as a scanning electron microscope (SEM) image. The imaging conditions are set to be an acceleration voltage of 2 kV and a magnification of 1,000 times, and an SEM image is obtained as the backscattered electron image.

Reading is carried out in grayscale with the cv2.imread ( ) function of Image processing library OpenCV 4 (manufactured by Intel Corporation) by setting the second argument to 0, and a binarized image is obtained with the cv2.threshold ( ) function, using an intermediate brightness between the high-brightness portion and the low-brightness portion as a boundary. A white portion (high-brightness portion) in the binarized image is defined as a magnetic particle.

Regarding the obtained binarized image, a rotational circumscribed rectangle corresponding to a portion of each magnetic particle is determined according to the cv2.minAreaRect ( ) function, and the long side length, the short side length, and the rotation angle are determined as the return values of the cv2.minAreaRect ( ) function. In a case of determining the total number of magnetic particles included in the binarized image, it shall be assumed that particles in which only a part of the particle is included in the binarized image are also included. Regarding the particles in which only a part of the particle is included in the binarized image, the long side length, the short side length, and the rotation angle of the portion included in the binarized image are determined. The ratio of the short side length to the long side length (short side length/long side length) determined in this way shall be denoted as the aspect ratio of each magnetic particle. In the present invention and the present specification, in a case where the number of magnetic particles which have an aspect ratio of 0.200 or less and is defined as flat-shaped particles is 10% or more on a number basis with respect to the total number of magnetic particles included in the binarized image, it shall be determined that the magnetic layer is a “magnetic layer including flat-shaped particles as the magnetic particles”. In addition, from the rotation angle determined as above, an “alignment angle” is determined as a rotation angle with respect to a horizontal plane (the surface of the magnetic layer).

Particles having an aspect ratio of 0.200 or less, which are determined in the binarized image, are defined as flat-shaped particles. Regarding the alignment angles of all the flat-shaped particles included in the binarized image, the sum of the absolute value of the average value (arithmetic average) and the variance is determined. The sum determined in this way is referred to as the “alignment degree”. It is noted that the coordinates of the circumscribed rectangle are calculated using the cv2.boxPoints ( ) function, and an image in which the rotational circumscribed rectangle is superposed on the original image is created according to the cv2.drawContours ( ) function, where a rotational circumscribed rectangle that is erroneously detected clearly is excluded from the calculation of the aspect ratio and the alignment degree. In addition, an average value (arithmetic average) of the aspect ratios of the particles defined as the flat-shaped particles shall be denoted as the aspect ratio of the flat-shaped particles to be contained in a magnetic layer to be measured. Such an aspect ratio is 0.200 or less, preferably 0.150 or less, and more preferably 0.100 or less. In addition, the aspect ratio can be, for example, 0.010 or more, 0.020 or more, or 0.030 or more.

The content of the magnetic particles in the magnetic layer can be, for example, 50 parts by mass or more, 60 parts by mass or more, 70 parts by mass or more, or 80 parts by mass or more, and can be, for example, 87 parts by mass or less, 85 parts by mass or less, 80 parts by mass or less, or 75 parts by mass or less, with respect to 100 parts by mass of the total mass of the magnetic layer. The magnetic layer can contain only one kind of magnetic particle, or can contain two or more kinds of magnetic particles at any ratio. In the present invention and the present specification, in a case where two or more kinds of components are contained, the content refers to a total content of the components. The contents of various components in the magnetic layer can be determined by a well-known method such as thermogravimetry/differential thermal analysis (TG/DTA) or extraction of various components using a solvent. In a case where a composition of a composition for forming a magnetic layer, which has been used for forming the magnetic layer, is known, the contents of various components in the magnetic layer can be also determined from this known composition.

In one form, the magnetic layer can be a layer having insulating properties. In the present invention and the present specification, the “insulating properties” means that the electrical conductivity is smaller than 1 siemens (S)/m. The electrical conductivity of a certain layer is calculated according to the following expression from the surface electrical resistivity of the layer and the thickness of the layer. The electrical conductivity can be measured by a known method.

$$Electrical conductivity [ S / m ] = 1 / ( surface electrical resistivity [ Ω ] \times thickness [ m ] )$$

The inventors of the present invention presume that it is preferable that the magnetic layer is a layer having insulating properties in order for the electromagnetic wave shielding material to exhibit a higher electromagnetic wave shielding ability. From this point, the electrical conductivity of the magnetic layer is preferably smaller than 1 S/m, more preferably 0.5 S/m or less, still more preferably 0.1 S/m or less, and even still more preferably 0.05 S/m or less. The electrical conductivity of the magnetic layer can be, for example, 1.0×10⁻¹² S/m or more or 1.0×10⁻¹⁰ S/m or more.

### (Acrylic Resin)

In the present invention and the present specification, a layer containing both magnetic particles and a resin shall correspond to the “magnetic layer”. The resin can act as a binder in the magnetic layer. In addition, at least a part of the resin can be contained in the magnetic layer in a state of forming a crosslinking structure with a crosslinking agent, the details of which will be described later. In the electromagnetic wave shielding material, the magnetic layer sandwiched between the two metal layers contains an acrylic resin. In the present invention and the present specification, the “acrylic resin” refers to a polymer of (meth)acrylate compound. The polymer includes a homopolymer and a copolymer. In the present invention and the present specification, the “(meth)acrylate compound” refers to a compound containing one or more (meth)acryloyl groups in one molecule, and the term “(meth)acryloyl group” is used to indicate one or both of an acryloyl group and a methacryloyl group. In addition, the (meth)acryloyl group can be included in the (meth)acrylate compound in the form of a (meth)acryloyloxy group. The term “(meth)acryloyloxy group” shall be used to refer to either or both of an acryloyloxy group and a methacryloyloxy group.

Examples of the (meth)acrylate compound include acrylic acid esters such as methyl acrylate, ethyl acrylate, butyl acrylate such as n(normal)-butyl acrylate, isobutyl acrylate, and t(tertiary)-butyl acrylate, cyclohexyl acrylate, hexyl acrylate, heptyl acrylate, octyl acrylate, and benzyl acrylate; and methacrylic acid esters such as methyl methacrylate, ethyl methacrylate, propyl methacrylate, n-butyl methacrylate, isobutyl methacrylate, t-butyl methacrylate, cyclohexyl methacrylate, hexyl methacrylate, and benzyl methacrylate. These may be used alone or in combination of two or more. The inventors of the present invention speculate that the polymer of acrylic acid ester (including a homopolymer and a copolymer) can contribute to a higher cross-linking degree of the magnetic layer, as compared with the polymer of methacrylic acid ester (including a homopolymer and a copolymer). In addition, the inventors of the present invention consider that the polymer of acrylic acid ester (including a homopolymer and a copolymer) tends to lower the glass transition temperature Tg of the magnetic layer, as compared with the polymer of methacrylic acid ester (including a homopolymer and a copolymer).

In one form, the acrylic resin can have an alkyl (meth)acrylate structure. In the present invention and the present specification, the “alkyl (meth)acrylate structure” refers to a partial structure represented by Formula A.

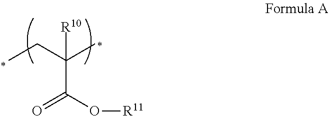

In Formula A, R¹⁰ represents a hydrogen atom or a methyl group. In a case where R¹⁰ is a hydrogen atom, the partial structure represented by Formula A is referred to as an alkyl acrylate structure, and in a case where R¹⁰ is a methyl group, the partial structure represented by Formula A is referred to as an alkyl methacrylate structure, and the term “alkyl (meth)acrylate structure” is used to include these. In the present invention and the present specification, “*” in the partial structure indicates a bonding position at which the partial structure is bonded to another partial structure. The acrylic resin can be a homopolymer or a copolymer including one or two or more kinds of alkyl (meth)acrylate structures as a repeating unit.

In Formula A, R¹¹ represents an alkyl group. In the present invention and the present specification, regarding the alkyl (meth)acrylate structure, the number of carbon atoms in the alkyl group refers to the number of carbon atoms in the alkyl group represented by R¹¹ in Formula A. The alkyl group represented by R¹¹ can be an unsubstituted alkyl group or an alkyl group having a substituent, and is preferably the unsubstituted alkyl group. In a case where the alkyl group represented by R¹¹ is an alkyl group having a substituent, the number of carbon atoms in the alkyl group represented by R¹¹ shall refer to the number of carbon atoms in a portion other than the substituent. Examples of the substituent include an alkyl group (for example, an alkyl group having 1 to 6 carbon atoms), a hydroxy group, an alkoxy group (for example, an alkoxy group having 1 to 6 carbon atoms), and a halogen atom (for example, a fluorine atom, a chlorine atom, or a bromine atom). The glass transition temperature Tg of the magnetic layer can be affected by the structure of the acrylic resin contained in the magnetic layer. From the viewpoint of controlling the glass transition temperature Tg of the magnetic layer within the range described above, the number of carbon atoms in the alkyl group represented by R¹¹ is preferably 2 or more. In addition, from the above-described viewpoint, the number of carbon atoms in the alkyl group represented by R¹¹ is preferably 8 or less, more preferably 7 or less, and still more preferably 6 or less, 5 or less, and 4 or less in this order.

Examples of the acrylic resin include a copolymer of one or more selected from a hydroxy group-containing compound, an unsaturated carboxylic acid, and a compound represented by Formula 3 and a (meth)acrylate compound.

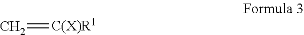

In Formula 3, R¹ represents a hydrogen atom or a methyl group, and X represents a hydrogen atom, an alkyl group having 1 to 20 carbon atoms, an aryl group, a —CN group, a —CO—R² group, a —O—CO—R³ group, a —O—R⁴ group, or a —(CH₂)ₙ—O—R⁵ group. R², R³, R⁴, and R⁵ each independently represent a hydrogen atom or an organic group having 1 to 20 carbon atoms, and the organic group may include a halogen atom, a glycidyl group, and the like. n represents an integer of 1 or more and 6 or less.

Examples of the hydroxy group-containing compound include 2-(hydroxyalkyl)acrylic acid esters such as α-hydroxymethylstyrene, α-hydroxyethylstyrene, and methyl 2-(hydroxyethyl)acrylate; 2-(hydroxyalkyl)acrylic acids such as 2-(hydroxyethyl)acrylic acid; and the like. These may be used alone or in combination of two or more kinds thereof.

Examples of the unsaturated carboxylic acid include acrylic acid, methacrylic acid, crotonic acid, α-substituted acrylic acid, and α-substituted methacrylic acid, and these may be used alone or in combination of two or more kinds thereof.

Examples of the compound represented by Formula 3 include styrene, vinyltoluene, α-methylstyrene, acrylonitrile, methyl vinyl ketone, ethylene, propylene, vinyl acetate, 2-chloroethyl vinyl ether, vinyl chloroacetate, allyl glycidyl ether, glycidyl methacrylate, and glycidyl acrylate, and these may be used alone or in combination of two or more.

As the acrylic resin contained in the magnetic layer, a commercially available acrylic resin or an acrylic resin synthesized by a known method can be used. For the synthesis method of the acrylic resin, for example, descriptions in paragraphs 0016 to 0038 and Examples of JP2002-140567A can be referred to.

From the viewpoint of further improving heat resistance and the viewpoint of self-supporting property of the magnetic layer, the content of the acrylic resin of the magnetic layer is preferably 5 parts by mass or more, more preferably 10 parts by mass or more, and still more preferably 15 parts by mass or more, with respect to 100 parts by mass of the total mass of the magnetic layer. In addition, from the viewpoint of further improving the shielding ability of the electromagnetic wave shielding material, the total content of the acrylic resin of the magnetic layer is preferably less than 30 parts by mass, more preferably 28 parts by mass or less, still more preferably 25 parts by mass or less, and still more preferably 20 parts by mass or less, with respect to 100 parts by mass of the total mass of the magnetic layer.

The magnetic layer can also contain, in addition to the above components, any amount of one or more known additives such as a crosslinking agent, a dispersing agent, a stabilizer (for example, an antioxidant, a light stabilizer such as a hindered amine light stabilizer (HALS), and the like), an anti-foaming agent, a metal adhesiveness improver, and a resin adhesiveness improver.

The crosslinking agent is a compound capable of forming a crosslinking structure, and can be contained in the magnetic layer in a state where the crosslinking structure is formed. The cross-linking degree of the magnetic layer can also be controlled by the amount of crosslinking agent used. From the viewpoint of controlling the cross-linking degree of the magnetic layer within the range described above, the content of the crosslinking agent of the magnetic layer is preferably 0.05 parts by mass or more and 2.00 parts by mass or less, and more preferably 0.05 parts by mass or more and 0.50 parts by mass or less, with respect to 100 parts by mass of the total mass of the magnetic layer.

Regarding the crosslinking agent, examples of the preferred crosslinking agent for controlling the cross-linking degree of the magnetic layer within the range described above include one or more crosslinking agents selected from the group consisting of a silane coupling agent and a polyfunctional amine compound.

The silane coupling agent is an organosilicon compound having an organic group and a hydrolyzable group. Examples of the hydrolyzable group include an alkoxy group, an acyloxy group, and a halogeno group.

The silane coupling agent may have a hydrophobic group. Examples of the silane coupling agent having a hydrophobic group as a functional group include alkoxysilanes such as methyltrimethoxysilane (MTMS), dimethyldimethoxysilane, phenyltrimethoxysilane, methyltriethoxysilane, dimethyldiethoxysilane, phenyltriethoxysilane, n-propyltrimethoxysilanes, n-propyltriethoxysilane, hexyltrimethoxysilane, hexyltriethoxysilane, and decyltrimethoxysilane; chlorosilanes such as methyltrichlorosilane, dimethyldichlorosilane, trimethylchlorosilane, and phenyltrichlorosilane; and hexamethyldisilazane (HMDS).

Further, the silane coupling agent may have a vinyl group. Examples of the silane coupling agent having a vinyl group include alkoxysilanes such as methacryloxypropyltriethoxysilane, methacryloxypropyltrimethoxysilane, methacryloxypropylmethyldiethoxysilane, methacryloxypropylmethyldimethoxysilane, vinyltriethoxysilane, vinyltrimethoxysilane, vinylmethyldimethoxysilane; chlorosilanes such as vinyltrichlorosilane and vinylmethyldichlorosilane; and divinyltetramethyldisilazane.

Further, the silane coupling agent may have an amino group. Examples of the silane coupling agent having an amino group include aminopropyltriethoxysilane, aminopropyltrimethoxysilane, N-2-(aminoethyl)-3-aminopropylmethyldimethoxysilane, N-2-(aminoethyl)-3-aminopropyltrimethoxysilane, N-2-(aminoethyl)-8-aminooctyltrimethoxysilane, a both-terminal amine type aminoalkoxysilane (for example, FM-3311, FM-3321, or FM-3325, manufactured by INC Corporation), and a polyfunctional amine type aminoalkoxysilane (for example, X-12-972F manufactured by Shin-Etsu Chemical Co., Ltd.).

Examples of the crosslinking structure that can be formed by the silane coupling agent include a crosslinking structure formed by hydrolysis and condensation of an alkoxysilane moiety of the silane coupling agent, and a crosslinking structure formed by a reaction between a functional group (for example, an amino group) of the silane coupling agent and a functional group (for example, a halogen atom) of the acrylic resin and by condensation of the alkoxysilane moiety.

The polyfunctional amine compound is a compound having two or more amino groups (—NH₂) in one molecule. As the polyfunctional amine compound, a diamine compound having two amino groups in one molecule is preferable. Specific examples of the diamine compound include diamine compounds described in the diamine monomer catalog of Tokyo Chemical Industry Co., Ltd. (URL: https://www.tcichemicals.com/assets/brochure-pdfs/Brochure_FF046_J.pdf). Examples of a more preferred diamine compound for controlling the cross-linking degree of the magnetic layer within the range described above include 1,8-octanediamine, 1,10-decanediamine, 1,12-dodecanediamine, 1,8-diamino-3,6-dioxaoctane, 1,4-bis(3-aminopropoxy)butane, bis[2-(3-aminopropoxy)]ethyl ether, triethylenetetramine, and N,N′-bis(2-aminoethyl)-1,3-propanediamine.

Examples of the crosslinking structure that can be formed by the polyfunctional amine compound include a crosslinking structure formed by a reaction between an amino group of the polyfunctional amine compound and a functional group (for example, a glycidyl group) of the acrylic resin.

The magnetic layer can contain one or more compounds selected from the group consisting of a compound represented by Formula 1 and a compound represented by Formula 2. The inventors of the present invention consider that such a compound can function as an adhesiveness improver such as a metal adhesiveness improver and a resin adhesiveness improver, and can contribute to improving the adhesiveness between two layers of the magnetic layer and the adjacent layer, that is, the adhesiveness between two layers of the magnetic layer and a layer directly in contact with the magnetic layer, without interposing another layer therebetween. An example of the layer directly in contact with the magnetic layer is a metal layer.

A force may be applied from the outside to the electromagnetic wave shielding material for forming, and even after the electromagnetic wave shielding material is formed and incorporated into an electronic component or an electronic apparatus, a force may be applied from the outside due to, for example, falling or collision. The durability to withstand such an external force can be shown as an example, as a desired performance of the electromagnetic wave shielding material. In a case where the adhesiveness between the two layers directly in contact with each other in the electromagnetic wave shielding material is high, peeling between the magnetic layer and the metal layer is less likely to occur in a case where a force is applied to the electromagnetic wave shielding material from the outside. It is preferable that such occurrence of peeling can be suppressed since this leads to improvement of the durability of the electromagnetic wave shielding material.

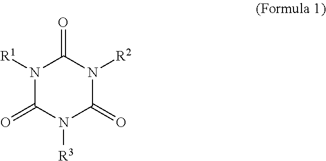

In Formula 1, R¹, R², and R³ each independently represent a hydrogen atom, an allyl group (CH₂═CH—CH₂—), an organic group including a hydroxy group (—OH), an organic group including a carboxy group (—COOH), an organic group including an alkoxysilyl group (—Si(OR)₃, where R represents an alkyl group), or a glycidyl group (epoxy group-CH₂—). R¹, R², and R³ may be the same as or different from each other, and two of R¹, R², and R³ may be the same as each other.

The organic group including a hydroxy group may be an organic group in which a hydroxy group is bonded to a divalent linking group. The divalent linking group is not particularly limited. The divalent linking group can be, for example, an unsubstituted hydrocarbon group or a substituted hydrocarbon group. With regard to the substituent included in the substituted hydrocarbon group, reference can be made to the description later on the substituent that can be included in the alkyl group R included in the alkoxysilyl group. Examples of the organic group including a hydroxy group include an organic group represented by —(CH₂)ₙ—OH. However, it is not limited to this example. The n represents an integer of 1 or more, and represents, for example, an integer in a range of 1 to 6.

The organic group including a carboxy group may be an organic group in which a carboxy group is bonded to a divalent linking group. The divalent linking group is not particularly limited. The divalent linking group can be, for example, an unsubstituted hydrocarbon group or a substituted hydrocarbon group. With regard to the substituent included in the substituted hydrocarbon group, reference can be made to the description later on the substituent that can be included in the alkyl group R included in the alkoxysilyl group. Examples of the organic group including a carboxy group include an organic group represented by —(CH₂)ₙ—COOH. However, it is not limited to this example. The n represents an integer of 1 or more, and represents, for example, an integer in a range of 1 to 6.

In the alkoxysilyl group (—Si(OR)₃), all of the three R's may be the same or all of the three R's may be different from each other, or two of the three R's may be the same. The alkyl group represented by R can be an unsubstituted alkyl group or an alkyl group having a substituent, and is preferably the unsubstituted alkyl group. In a case where the alkyl group represented by R is an alkyl group having a substituent, the number of carbon atoms in the alkyl group represented by R shall refer to the number of carbon atoms in a portion other than the substituent. Examples of the substituent that can be included in the alkyl group represented by R include an alkyl group (for example, an alkyl group having 1 to 6 carbon atoms), a hydroxy group, an alkoxy group (for example, an alkoxy group having 1 to 6 carbon atoms), and a halogen atom (for example, a fluorine atom, a chlorine atom, or a bromine atom). The number of carbon atoms of the alkyl group represented by R can be 1 or more and 2 or more. In addition, the number of carbon atoms of the alkyl group represented by R can be 8 or less, 7 or less, 6 or less, 5 or less, 4 or less, or 3 or less. The compound represented by Formula 1 may be present in the magnetic layer in a form in which the alkoxysilyl group is hydrolyzed.

The organic group including the alkoxysilyl group (—Si(OR)₃, where R represents an alkyl group) may be an organic group in which the alkoxysilyl group is bonded to a divalent linking group. The divalent linking group is not particularly limited. The divalent linking group can be, for example, an unsubstituted hydrocarbon group or a substituted hydrocarbon group. With regard to the substituent included in the substituted hydrocarbon group, reference can be made to the description above on the substituent that can be included in the alkyl group represented by R. Examples of the organic group including the alkoxysilyl group (—Si(OR)₃, where R represents an alkyl group) include an organic group represented by —(CH₂)ₙ—Si(OR)₃. However, it is not limited to this example. The n represents an integer of 1 or more, and represents, for example, an integer in a range of 1 to 6.

The compound represented by Formula 1 may have keto-enol tautomerism. In the case of a compound having keto-enol tautomerism, Formula 1 represents the form of a keto-type isomer. In the present invention and the present specification, for the compound having keto-enol tautomerism, the compound represented by Formula 1 shall also include those in a form of an enol-type isomer. As an example, an enol-type isomer of cyanuric acid (in Formula 1, R¹, R², and R³ represent hydrogen atoms) can be represented by Formula 1-1. In addition, the compound represented by Formula 1 may be present as a metal complex such as a zinc complex. In the present invention and the present specification, the compound represented by Formula 1 also includes a metal complex of the compound represented by Formula 1.

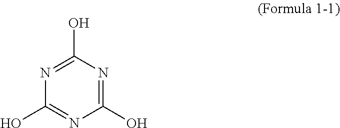

In addition, the compound represented by Formula 1 may be present as a mixture of the compound represented by Formula 1 and melamine. As an example of such a mixture, melamine cyanurate can be used. Melamine cyanurate is a mixture of melamine and cyanuric acid (in Formula 1, R¹, R², and R³ represent hydrogen atoms). Melamine is an example of a compound represented by Formula 2, which will be described in detail later. In melamine, R⁴, R⁵, and R⁶ in Formula 2 represent an amino group (—NH₂).

Specific examples of the compound represented by Formula 1 include cyanuric acid, a cyanuric acid-zinc complex, melamine cyanurate, diallyl monoglycidyl isocyanurate, monoallyl diglycidyl isocyanurate, tris[3-(trimethoxysilyl)propyl]isocyanurate, tris(2-hydroxyethyl) isocyanurate, tris(2-carboxyethyl) isocyanurate, and bis(2-carboxyethyl) isocyanurate. Specific examples of the commercially available product include STARFINE F-10 manufactured by Nissan Chemical Corporation, melamine cyanurate MC-4000, MC-4500, and MC-6000 manufactured by Nissan Chemical Corporation, and KBM-9659 manufactured by Shin-Etsu Chemical Co., Ltd. However, the compound represented by Formula 1 is not limited to the above specific examples.

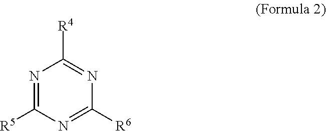

In Formula 2, R⁴, R⁵, and R⁶ each independently represent an amino group (—NH₂) or an organic group including an alkoxysilyl group (—Si(OR)₃, where R represents an alkyl group).

R⁴, R⁵, and R⁶ may be the same as or different from each other, and two of R⁴, R⁵, and R⁶ may be the same as each other.

For the alkoxysilyl group (—Si(OR)₃), reference can be made to the above description related to Formula 1. The compound represented by Formula 2 may be present in the magnetic layer in a form in which the alkoxysilyl group is hydrolyzed.

The organic group including the alkoxysilyl group (—Si(OR)₃, where R represents an alkyl group) may be an organic group in which the alkoxysilyl group is bonded to a divalent linking group. The divalent linking group is not particularly limited. The divalent linking group can be, for example, an unsubstituted hydrocarbon group, a substituted hydrocarbon group, a —NH— group, or a combination of two or more of these groups. With regard to the substituent included in the substituted hydrocarbon group, reference can be made to the description above on the substituent that can be included in the alkyl group represented by R. Examples of the organic group including the alkoxysilyl group (—Si(OR)₃, where R represents an alkyl group) include an organic group represented by —NH—(CH₂)ₙ—Si(OR)₃. However, it is not limited to this example. The n represents an integer of 1 or more, and represents, for example, an integer in a range of 1 to 6.

Specific examples of the commercially available product of the compound represented by Formula 2 include VD-5 manufactured by SHIKOKU CHEMICALS CORPORATION. In addition, as described above, examples of the compound represented by Formula 2 include melamine (in Formula 2, R⁴, R⁵, and R⁶ represent an amino group (—NH₂)), and the melamine may be present as a mixture with the compound represented by Formula 1. As a specific example of such a mixture, melamine cyanurate can be used. Specific examples of the commercially available product of the melamine cyanurate are as described above. However, the compound represented by Formula 2 is not limited to the above specific examples.

In a case where the magnetic layer contains one or more compounds selected from the group consisting of the compound represented by Formula 1 and the compound represented by Formula 2, the magnetic layer may contain only one or more compounds represented by Formula 1, may contain only one or more compounds represented by Formula 2, or may contain one or more compounds represented by Formula 1 and one or more compounds represented by Formula 2, as a compound selected from the group consisting of the compound represented by Formula 1 and the compound represented by Formula 2. In a case where the magnetic layer contains one or more compounds selected from the group consisting of the compound represented by Formula 1 and the compound represented by Formula 2, a content of these compounds (in a case of containing a plurality of kinds, a total content thereof) in the magnetic layer is, for example, 0.01 parts by mass or more and 4.00 parts by mass or less with respect to 100 parts by mass of the total mass of the magnetic layer. In a case where the compound represented by Formula 1 is a metal complex, the content refers to a content as the metal complex.

The inventors of the present invention speculate that it is preferable from the viewpoint of improving formability of the electromagnetic wave shielding material that the magnetic layer contains one or more compounds selected from the group consisting of the compound represented by Formula 1 and the compound represented by Formula 2. The inventors of the present invention consider that the compound which is more preferable from the viewpoint of improving formability is the compound represented by Formula 1.

In a case where the electromagnetic wave shielding material includes only one magnetic layer, the thickness of this one magnetic layer can be, for example, 5 μm or more, and it is preferably 10 μm or more and more preferably 20 μm or more from the viewpoint of further improving the shielding ability of the electromagnetic wave shielding material. Meanwhile, the thickness of this one magnetic layer can be, for example, 100 μm or less or 90 m or less, and it is preferably less than 90 m, more preferably 80 μm or less, and still more preferably 70 μm or less, from the viewpoint of further improving formability.

In a case where the electromagnetic wave shielding material includes two or more magnetic layers, the thickness of each of the two or more magnetic layers (that is, the thickness per one layer) can be, for example, 5 μm or more, and it is preferably 10 μm or more and more preferably 20 μm or more from the viewpoint of further improving the shielding ability of the electromagnetic wave shielding material. Meanwhile, the thickness of each of the two or more magnetic layers can be, for example, 100 μm or less or 90 μm or less, and it is preferably less than 90 μm and more preferably 80 μm or less. The respective thicknesses of the two or more magnetic layers can be the same thickness or thicknesses different from each other.

The thickness of each layer included in the electromagnetic wave shielding material shall be determined by imaging a cross section exposed by a known method with a scanning electron microscope (SEM) and determining an arithmetic average of thicknesses of five randomly selected points in the obtained SEM image.

### <Metal Layer>

The electromagnetic wave shielding material has a multilayer structure in which the magnetic layer is sandwiched between two metal layers. The electromagnetic wave shielding material has one or more such multilayer structures and can also include two or more such multilayer structures. That is, the electromagnetic wave shielding material includes at least two metal layers and can also include three or more layers of metal layer, or it includes at least one magnetic layer and can also include two or more magnetic layers. The two or more layers of metal layer included in the electromagnetic wave shielding material have the same composition and thickness in one form and differ in composition and/or thickness in another form. The same applies to a case where the electromagnetic wave shielding material includes two or more magnetic layers, and the same applies to a case where two or more other layers such as a resin layer described later are included in the electromagnetic wave shielding material.

In the present invention and the present specification, the “metal layer” shall refer to a layer containing a metal. The metal layer can be a layer containing one or more kinds of metals as a pure metal consisting of a single metal element, as an alloy of two or more kinds of metal elements, or as an alloy of one or more kinds of metal elements and one or more kinds of non-metal elements.

The metal layer included in the electromagnetic wave shielding material can be a layer that contains one or more kinds of metals selected from the group consisting of various pure metals and various alloys. The metal layer can exhibit an attenuation effect in the electromagnetic wave shielding material. This point is preferable from the viewpoint of improving the shielding ability of the electromagnetic wave shielding material. Since the attenuation effect increases as the propagation constant increases and the propagation constant increases as the electrical conductivity is higher, it is preferable that the metal layer contains a metal element having a high electrical conductivity. From this point, it is preferable that the metal layer contains, as a main component, a pure metal of Ag, Cu, Au, or Al, or an alloy containing any one of these. The pure metal is a metal consisting of a single metal element and may contain a trace amount of impurities. In general, a metal having a purity of 99.0% or more consisting of a single metal element is called a pure metal. The purity is on a mass basis. The alloy is generally prepared by adding one or more kinds of metal elements or non-metal elements to a pure metal to adjust the composition, for example, in order to prevent corrosion or improve the hardness. The main component in the alloy is a component having the highest ratio on a mass basis, and it can be, for example, a component that occupies 80.0% by mass or more (for example, 99.8% by mass or less) in the alloy. From the viewpoint of economic efficiency, the alloy is preferably an alloy of a pure metal of Cu or Al or an alloy containing Cu or Al as a main component, and from the viewpoint of high electrical conductivity, it is more preferably an alloy of a pure metal of Cu or an alloy containing Cu as a main component.

In one form, the purity of the metal in the metal layer, that is, the content of the metal in the metal layer can be 99.0% by mass or more, 99.5% by mass or more, or 99.8% by mass or more with respect to the total mass of the metal layer. Unless otherwise specified, the content of metal in the metal layer shall refer to the content on a mass basis. For example, as the metal layer, a pure metal or an alloy processed into a sheet shape can be used. For example, as the metal layer, a commercially available metal foil or a metal foil produced by a known method can be used. Regarding a pure metal of Cu, sheets (so-called copper foils) having various thicknesses are commercially available. For example, such a copper foil can be used as the metal layer. The copper foil includes, according to manufacturing methods thereof, an electrolytic copper foil obtained by precipitating a copper foil on a cathode by electroplating and a rolled copper foil obtained by applying heat and pressure to an ingot and stretching the ingot thinly. Any copper foil can be used as the metal layer of the electromagnetic wave shielding material. In addition, for example, regarding Al, sheets (so-called aluminum foils) having various thicknesses are commercially available. For example, such an aluminum foil can be used as the metal layer.

From the viewpoint of reducing the weight of the electromagnetic wave shielding material, one or both (preferably both) of the two metal layers sandwiching the magnetic layer is preferably a metal layer containing the metal selected from the group consisting of Al and Mg, and more preferably a layer containing, as a main component, the metal selected from the group consisting of Al and Mg. The main component of the metal layer is a component having the highest ratio on a mass basis. In a layer containing, as a main component, a metal selected from the group consisting of Al and Mg, Al or Mg is a component having the highest ratio on a mass basis in this layer. Such a layer may contain only Al or Mg among Al and Mg, or may contain Al and Mg. A value (specific gravity/electrical conductivity) obtained by dividing the specific gravity by the electrical conductivity is small both in Al and Mg. As a metal in which this value is smaller is used, the weight of the electromagnetic wave shielding material that exhibits a high shielding ability can be further reduced. As a value calculated from the literature value, for example, a value (specific gravity/electrical conductivity) obtained by dividing the specific gravity by the electrical conductivity of each of Cu, Al, and Mg is as follows. Cu: 1.5×10⁻⁷ m/S, Al: 7.6×10⁻⁸ m/S, Mg: 7.6×10⁻⁸ m/S. From the above values, it can be said that Al and Mg are preferred metals from the viewpoint of reducing the weight of the electromagnetic wave shielding material. The metal layer containing a metal selected from the group consisting of Al and Mg can contain only one of Al and Mg in one form and can contain both in another form. From the viewpoint of reducing the weight of the electromagnetic wave shielding material, one or both (preferably both) of the two metal layers sandwiching the magnetic layer is preferably a metal layer in which the content of the metal selected from the group consisting of Al and Mg is 80.0% by mass or more, and still more preferably a metal layer in which the content of the metal selected from the group consisting of Al and Mg is 90.0% by mass or more. The metal layer containing at least Al among Al and Mg can be a metal layer in which the Al content is 80.0% by mass or more, and it can be a metal layer in which the Al content is 90.0% by mass or more. The metal layer containing at least Mg among Al and Mg can be a metal layer in which the Mg content is 80.0% by mass or more, and it can be a metal layer in which the Mg content is 90.0% by mass or more. The content of the metal selected from the group consisting of Al and Mg, the Al content, and the Mg content can be each, for example, 99.9% by mass or less. The content of the metal selected from the group consisting of Al and Mg, the Al content, and the Mg content are each the content with respect to the total mass of the metal layer.

From one or more viewpoints of the viewpoint of economic efficiency, the viewpoint of high electrical conductivity, and the viewpoint of reducing the weight of the electromagnetic wave shielding material, one or both (preferably both) of the two metal layers sandwiching the magnetic layer is preferably a metal layer containing the metal selected from the group consisting of Al, Mg, and Cu, and more preferably a layer containing, as a main component, the metal selected from the group consisting of Al, Mg, and Cu. In a layer containing, as a main component, a metal selected from the group consisting of Al, Mg, and Cu, Al, Mg, or Cu is a component having the highest ratio on a mass basis in this layer. Such a layer can contain only one kind of metal or two or three kinds of metals among Al, Mg, and Cu. From the one or more viewpoints, one or both (preferably both) of the two metal layers sandwiching the magnetic layer is preferably a metal layer in which the content of the metal selected from the group consisting of Al, Mg, and Cu is 80.0% by mass or more, and still more preferably a metal layer in which the content of the metal selected from the group consisting of Al, Mg, and Cu is 90.0% by mass or more. The metal layer containing at least Al among Al, Mg, and Cu can be a metal layer in which the Al content is 80.0% by mass or more, and it can be a metal layer in which the Al content is 90.0% by mass or more. The metal layer containing at least Mg among Al, Mg, and Cu can be a metal layer in which the Mg content is 80.0% by mass or more, and it can be a metal layer in which the Mg content is 90.0% by mass or more. The metal layer containing at least Cu among Al, Mg, and Cu can be a metal layer in which the Cu content is 80.0% by mass or more, and it can be a metal layer in which the Cu content is 90.0% by mass or more. The content of the metal selected from the group consisting of Al, Mg, and Cu, the Al content, the Mg content, and the Cu content can be each, for example, 99.9% by mass or less. The content of the metal selected from the group consisting of Al, Mg, and Cu, the Al content, the Mg content, and the Cu content are each the content with respect to the total mass of the metal layer.

From the viewpoint of further improving the processability of the metal layer and the shielding ability of the electromagnetic wave shielding material, the thickness of the metal layer in terms of the thickness per one layer is preferably 4 μm or more, more preferably 5 μm or more, and still more preferably 10 μm or more. On the other hand, from the viewpoint of the processability of the metal layer, the thickness of the metal layer in terms of the thickness per one layer is preferably 200 μm or less, more preferably 100 μm or less, and still more preferably 50 μm or less. In the electromagnetic wave shielding material, the thicknesses of the plurality of metal layers can be the same thickness or thicknesses different from each other.

In one form, one or both of the outermost layers can be a metal layer in the electromagnetic wave shielding material. This point can contribute to the fact that the electromagnetic wave shielding material can exhibit a high shielding ability against a magnetic field wave in a low frequency region of about 100 kHz to 1 MHz. In addition, the fact that at least one of the outermost layers of the electromagnetic wave shielding material is a metal layer can contribute to suppressing edge peeling in a formed article obtained by forming processing. In one form, one or both of the outermost layers of the electromagnetic wave shielding material can be a metal layer that sandwiches a magnetic layer together with another metal layer.

In one form, in the multilayer structure in which the magnetic layer is sandwiched between the two metal layers of the electromagnetic wave shielding material, one or both of the two metal layers and the magnetic layer can be disposed as layers directly in contact with each other. That is, one or both of the two metal layers and the magnetic layer can be adjacent to each other without interposing another layer. In addition, in one form, a multilayer structure in which the magnetic layer is sandwiched between the two metal layers of the electromagnetic wave shielding material can also include one or more layers containing a resin, provided between one or both of the two metal layers and the magnetic layer. The layer containing a resin is a layer containing one or more kinds of resins. Hereinafter, a specific form of the layer containing a resin will be described.

### <Layer Containing Resin>

### (Pressure-Sensitive Adhesive Layer)

A pressure-sensitive adhesive layer can be mentioned as one form of the layer containing a resin. In the present invention and the present specification, the “pressure-sensitive adhesive layer” refers to a layer having tackiness on a surface at normal temperature. Regarding the tackiness, the “normal temperature” shall be defined as 23° C. In a case where such a layer comes into contact with an adherend, the layer adheres to the adherend due to the adhesive force thereof. In general, the tackiness is the property of exhibiting an adhesive force in a short time after coming into contact with an adherend with a very light force, and in the present invention and the present specification, the above-described “having tackiness” refers to that the result is No. 1 to No. 32 in a tilted ball tack test (measurement environment: a temperature of 23° C. and a relative humidity of 50%) specified in JIS Z 0237: 2009. In a case where another layer is laminated on the surface of the pressure-sensitive adhesive layer, the surface of the pressure-sensitive adhesive layer exposed, for example, by peeling off the other layer can be subjected to the above-described test. In a case where another layer is laminated on each of one surface and the other surface of the pressure-sensitive adhesive layer, the layer on the side of either surface may be peeled off.

As the pressure-sensitive adhesive layer, it is possible to use those obtained by applying a composition for forming a pressure-sensitive adhesive layer containing a pressure sensitive adhesive such as an acrylic pressure sensitive adhesive, a rubber-based pressure-sensitive adhesive, a silicone-based pressure-sensitive adhesive, or a urethane-based pressure-sensitive adhesive and processing it into a film shape.

The composition for forming a pressure-sensitive adhesive layer can be applied onto, for example, a support. The coating can be carried out using a known coating device such as a blade coater or a die coater. The coating can be carried out by a so-called roll-to-roll method or a batch method.

Examples of the support onto which the composition for forming a pressure-sensitive adhesive layer is applied include films of various resins such as polyester such as polyethylene terephthalate (PET) and polyethylene naphthalate (PEN), acryls such as polycarbonate (PC) and polymethyl methacrylate (PMMA), cyclic polyolefin, triacetyl cellulose (TAC), polyether sulfide (PES), polyether ketone, and polyimide. As the support, it is possible to use a support in which a surface (a surface to be coated) onto which the composition for forming a pressure-sensitive adhesive layer is applied is subjected to a peeling treatment according to a known method. One form of the peeling treatment includes forming a release layer. In addition, a commercially available peeling-treated resin film can also be used as the support. In a case of using a support in which the surface to be coated is subjected to the peeling treatment, it is possible to easily separate the pressure-sensitive adhesive layer and the support after the film formation.

By applying a composition for forming a pressure-sensitive adhesive layer, in which a pressure sensitive adhesive is dissolved and/or dispersed in a solvent, onto the surface to be coated and carrying out drying, a pressure-sensitive adhesive layer can be formed. Alternatively, a pressure sensitive adhesive tape including a pressure-sensitive adhesive layer can also be used. As the pressure sensitive adhesive tape, for example, it is possible to use a double-sided tape. The double-sided tape has pressure-sensitive adhesive layers on both sides of the support. In addition, as the pressure sensitive adhesive tape, it is possible to use a pressure sensitive adhesive tape having a pressure-sensitive adhesive layer on one surface of a support. Examples of the support include films of various resins such as polyester such as polyethylene terephthalate (PET) and polyethylene naphthalate (PEN), acryls such as polycarbonate (PC) and polymethyl methacrylate (PMMA), cyclic polyolefin, triacetyl cellulose (TAC), polyether sulfide (PES), polyether ketone, and polyimide, a non-woven fabric, and paper. As the pressure sensitive adhesive tape having a pressure-sensitive adhesive layer on one surface or both surfaces of a support, it is possible to use a commercially available product, or it is possible to use a pressure sensitive adhesive tape produced by a known method.

The thickness of the pressure-sensitive adhesive layer is not particularly limited, and the thickness per layer can be, for example, 1 μm or more and 30 μm or less.

### (Adhesive Layer)

An adhesive layer can also be mentioned as one form of the layer containing a resin. In the present invention and the present specification, the “adhesive layer” is a layer in which a liquid or gel-like adhesive is solidified after coming into contact with an adherend and undergoing a state change such as drying or curing, at that time, adhesiveness to the adherend is exhibited by an anchoring effect, a physical interaction, or formation of a chemical bond to the adherend. In one form, the adhesive layer can be a layer having no tackiness on the surface at normal temperature.

The adhesive contains a resin that is solidified after being dried or cured. Examples of such a resin include a vinyl acetate resin, an ethylene vinyl acetate resin, an epoxy resin, a cyanoacrylate resin, an acrylic resin, a polyurethane resin, a chloroprene rubber, and a styrene butadiene rubber. These resins may be in the form of a liquid or a gel in the resin itself. Alternatively, the solid resin may be dissolved in a solvent to be in a liquid or gel form. Examples of the solvent contained in the adhesive include water, ketone-based solvents such as acetone, methyl ethyl ketone, and cyclohexanone, acetic acid ester-based solvents such as ethyl acetate, butyl acetate, cellosolve acetate, propylene glycol monomethyl ether acetate, and carbitol acetate, carbitols such as cellosolve and butyl carbitol, aromatic hydrocarbon-based solvents such as toluene and xylene, and amide-based solvents such as dimethylformamide, dimethylacetamide, and N-methylpyrrolidone, alcohol-based solvents such as ethanol, methanol, and propanol, and halogen-based solvents such as dichloromethane, trichloroethylene, and dichlorofluoroethane.

The thickness of the adhesive layer is not particularly limited, and the thickness per layer can be, for example, 1 μm or more and 30 μm or less.

### (Resin Layer)

A resin layer can also be mentioned as one form of the layer containing a resin. In the present invention and the present specification, the “resin layer” is a resin film obtained by forming a thermoplastic resin such as a synthetic resin into a film shape, and the resin film has a film-like structure by itself and does not have tackiness at normal temperature.

Examples of the thermoplastic resin contained in the resin film include various resins such as a polyethylene (PE) resin, a polypropylene (PP) resin, a polyvinyl chloride (PVC) resin, a polystyrene (PS) resin, a vinyl acetate resin, a polyurethane resin, a polyvinyl alcohol resin, an ethylene vinyl acetate resin, styrene butadiene rubber, acrylonitrile butadiene rubber, silicone rubber, an olefin-based elastomer (PP), a styrene-based elastomer, an acrylonitrile-butadiene-styrene (ABS) resin, polyethylene terephthalate (PET), a polyester resin such as polyethylene naphthalate (PEN), a polycarbonate (PC) resin, an acrylic resin such as polymethyl methacrylate (PMMA), cyclic polyolefin, and triacetyl cellulose (TAC).

The resin layer can be bonded to a metal layer or a magnetic layer by interposing a pressure-sensitive adhesive layer or an adhesive layer. In addition, since the resin layer is a layer containing a thermoplastic resin, the resin layer has the property of being softened by heating and flows and follows minute protrusions and recessions on the surface of the adherend by being pressed against the adherend in a state of being heated, thereby capable of exhibiting an adhesive force due to the anchoring effect, and then it is cooled, whereby the adhered state can be maintained. Therefore, in one form, the resin layer and the other layer can be bonded to each other without interposing the pressure-sensitive adhesive layer or the adhesive layer.

The thickness of the resin layer in terms of the thickness per one resin layer is preferably 10 μm or greater and more preferably 12 μm or greater. The thickness of the resin layer in terms of the thickness per one resin layer is preferably 250 μm or less, more preferably 230 μm or less, still more preferably 210 μm or less, and even still more preferably 190 μm or less. In one form, the electromagnetic wave shielding material can include, in a multilayer structure in which the magnetic layer is sandwiched between the two metal layers, one or more resin layers having a thickness in the above range between one or both of the two metal layers and the magnetic layer. For example, the multilayer structure can include one resin layer having a thickness in the above range between one metal layer of the two metal layers and the magnetic layer and/or between the other metal layer and the magnetic layer.

The electromagnetic wave shielding material can contain, in one or more layers containing a resin, one or more compounds selected from the group consisting of a compound represented by Formula 1 and a compound represented by Formula 2. The layer containing such a compound can be one or more layers selected from the group consisting of the pressure-sensitive adhesive layer, the adhesive layer, and the resin layer. In a case where the layer containing a resin contains one or more compounds selected from the group consisting of the compound represented by Formula 1 and the compound represented by Formula 2, the above description related to a case where such a compound is contained in the magnetic layer can be referred to.

### <Specific Example of Layer Configuration>

The total number of the magnetic layers included in the electromagnetic wave shielding material is such that one or more layers are included, two or more layers can be included, and for example, four or less layers can be included.

On the other hand, the total number of the metal layers included in the electromagnetic wave shielding material is such that two or more layers are included, and for example, two to five layers can be included.

In a case where the electromagnetic wave shielding material includes only one magnetic layer, this one magnetic layer is a magnetic layer sandwiched between the two metal layers.

In a case where the electromagnetic wave shielding material includes two or more magnetic layers, at least one layer of these two or more magnetic layers is a magnetic layer sandwiched between the two metal layers. Specifically, all or only a part of the magnetic layers included in the electromagnetic wave shielding material is a magnetic layer sandwiched between the two metal layers.

In one form, in a multilayer structure in which the magnetic layer is sandwiched between two metal layers, the magnetic layer can be in direct contact with both metal layers. In this case, specific examples of the layer configuration of the electromagnetic wave shielding material include the following examples.
Example A1: “Metal layer/magnetic layer/metal layer”
Example A2: “Metal layer/magnetic layer/metal layer/magnetic layer/metal layer”
Example A3: “Metal layer/magnetic layer/metal layer/magnetic layer/metal layer/magnetic layer/metal layer”

In an electromagnetic wave shielding material having two or more multilayer structures that include the magnetic layer between two metal layers, for example, as in Example A2 and Example A3, a metal layer that sandwiches a magnetic layer in a certain multilayer structure can also be a metal layer that sandwiches a magnetic layer in another multilayer structure. In the electromagnetic wave shielding material, the total number of multilayer structures including the magnetic layer between two metal layers can be, for example, 1 to 4. The total number of the multilayer structures is one in Example A1, two in Example A2, and three in Example A3. It is preferable that the total number of the multilayer structures is two or more (for example, two, three, or four) from the viewpoint of further improving the shielding ability of the electromagnetic wave shielding material. In the above, the symbol “/” means that the layer described on the left side of this symbol and the layer described on the right side of this symbol are in direct contact with each other without another layer being interposed therebetween. This point is also the same in the following description unless otherwise noted.

In another form, a multilayer structure in which the magnetic layer is sandwiched between the two metal layers of the electromagnetic wave shielding material can include one or more layers containing a resin between one or both of the two metal layers and the magnetic layer. In the above-described multilayer structure, one of the two metal layers may be adjacent to the magnetic layer without interposing another layer, and one or more layers containing a resin may be included between the other metal layer and the magnetic layer. In addition, the multilayer structure may include one or more layers containing a resin, provided between each of the two metal layers and the magnetic layer. The layer containing a resin, which is located between the metal layer and the magnetic layer, is preferably at least a resin layer. In one form, the electromagnetic wave shielding material can include one or more layers containing a polyester resin between one or both of the two metal layers and the magnetic layer, and the layer containing a polyester resin is preferably a resin layer.

The multilayer structure can include a pressure-sensitive adhesive layer and/or an adhesive layer between the resin layer and the metal layer. In one form, in the multilayer structure, the pressure-sensitive adhesive layer and/or the adhesive layer may be included between the resin layer and the magnetic layer. In another form, in the multilayer structure, the resin layer and the magnetic layer can be in direct contact with each other. That is, the resin layer and the magnetic layer can be adjacent to each other without interposing another layer.

The electromagnetic wave shielding material can include, for example, a total of 1 to 12 layers containing a resin. The total number of layers of resin layers (preferably the resin layers having the thickness described above) included in the electromagnetic wave shielding material can be, for example, one to four layers. The total number of layers of layers selected from the group consisting of the pressure-sensitive adhesive layer and the adhesive layer, which are included in the electromagnetic wave shielding material, can be, for example, one to four layers or one to eight layers.

Examples of the disposition of the “magnetic layer”, the “metal layer”, the “resin layer”, and the “pressure-sensitive adhesive layer or adhesive layer” in the electromagnetic wave shielding material include the following examples. In the following examples, the “pressure-sensitive adhesive layer” may include a support, and the “pressure-sensitive adhesive layer” may be a pressure sensitive adhesive tape having a pressure-sensitive adhesive layer on one or both surfaces of the support. For example, as in Example B3, metal layers that sandwich a certain magnetic layer can be metal layers that sandwich another magnetic layer. For example, in Example B3, the metal layer 2 is one of the two metal layers that sandwich the magnetic layer 1, and it is also one of the two metal layers that sandwich the magnetic layer 2. In addition, in Example B3, one of the outermost layers of the electromagnetic wave shielding material is the metal layer 1 that sandwiches the magnetic layer 1 together with the metal layer 2, and the other of the outermost layers of the electromagnetic wave shielding material is the metal layer 3 that sandwiches the magnetic layer 2 together with the metal layer 2.
Example B1: “Metal layer 1/pressure-sensitive adhesive layer 1 or adhesive layer 1/resin layer 1/magnetic layer 1/resin layer 2/pressure-sensitive adhesive layer 2 or adhesive layer 2/metal layer 2”
Example B2: “Metal layer 1/pressure-sensitive adhesive layer 1 or adhesive layer 1/resin layer 1/magnetic layer 1/metal layer 2/pressure-sensitive adhesive layer 2 or adhesive layer 2/resin layer 2”
Example B3: “Metal layer 1/pressure-sensitive adhesive layer 1 or adhesive layer 1/resin layer 1/magnetic layer 1/resin layer 2/pressure-sensitive adhesive layer 2 or adhesive layer 2/metal layer 2/pressure-sensitive adhesive layer 3 or adhesive layer 3/resin layer 3/magnetic layer 2/resin layer 4/pressure-sensitive adhesive layer 4 or adhesive layer 4/metal layer 3”
Example B4: “Metal layer 1/pressure-sensitive adhesive layer 1 or adhesive layer 1/resin layer 1/magnetic layer 1/metal layer 2/pressure-sensitive adhesive layer 2 or adhesive layer 2/resin layer 2/magnetic layer 2/resin layer 3/pressure-sensitive adhesive layer 3 or adhesive layer 3/metal layer 3”
Example B5: “Metal layer 1/pressure-sensitive adhesive layer 1 or adhesive layer 1/resin layer 1/magnetic layer 1/metal layer 2/pressure-sensitive adhesive layer 2 or adhesive layer 2/resin layer 2/magnetic layer 2/metal layer 3/pressure-sensitive adhesive layer 3 or adhesive layer 3/resin layer 3”
Example B6: “Metal layer 1/pressure-sensitive adhesive layer 1 or adhesive layer 1/resin layer 1/magnetic layer 1/metal layer 2/magnetic layer 2/resin layer 2/pressure-sensitive adhesive layer 2 or adhesive layer 2/metal layer 3”
Example B7: “Metal layer 1/pressure-sensitive adhesive layer 1 or adhesive layer 1/resin layer 1/magnetic layer 1/metal layer 2/magnetic layer 2/metal layer 3/pressure-sensitive adhesive layer 2 or adhesive layer 2/resin layer 2”
Example B8: “Metal layer 1/pressure-sensitive adhesive layer 1 or adhesive layer 1/resin layer 1/magnetic layer 1/resin layer 2/pressure-sensitive adhesive layer 2 or adhesive layer 2/metal layer 2/magnetic layer 2/resin layer 3/pressure-sensitive adhesive layer 3 or adhesive layer 3/metal layer 3”

In another form, a multilayer structure in which the magnetic layer is sandwiched between the two metal layers of the electromagnetic wave shielding material can be a multilayer structure in which two or more magnetic layers are sandwiched between the two metal layers. Such a multilayer structure can also include one or more layers containing a resin between the two adjacent magnetic layers. For example, a multilayer structure in which the magnetic layer is sandwiched between the two metal layers of the electromagnetic wave shielding material can include two magnetic layers between the two metal layers, and can include one layer containing a resin between the two magnetic layers. Specific examples of the layer configuration of the electromagnetic wave shielding material having such a multilayer structure include the following Example B9.
Example B9: “Metal layer 1/magnetic layer 1/resin layer 1/magnetic layer 2/metal layer 2”

### <Manufacturing Method for Electromagnetic Wave Shielding Material>

### (Film Forming Method for Magnetic Layer)

The magnetic layer can be produced, for example, by drying a coating layer that is provided by applying a composition for forming a magnetic layer. The composition for forming a magnetic layer can contain the components described above and can further contain one or more kinds of solvents. Examples of the solvent include various organic solvents, for example, ketone-based solvents such as acetone, methyl ethyl ketone, and cyclohexanone, acetic acid ester-based solvents such as ethyl acetate, butyl acetate, cellosolve acetate, propylene glycol monomethyl ether acetate, and carbitol acetate, carbitols such as cellosolve and butyl carbitol, aromatic hydrocarbon-based solvents such as toluene and xylene, and amide-based solvents such as dimethylformamide, dimethylacetamide, and N-methylpyrrolidone. One kind of solvent or two or more kinds of solvents selected in consideration of the solubility of the component that is used in the preparation of the composition for forming a magnetic layer can be mixed at any ratio and used. The solvent content of the composition for forming a magnetic layer is not particularly limited and may be determined in consideration of the coatability of the composition for forming a magnetic layer.

The composition for forming a magnetic layer can be prepared by sequentially mixing various components in any order or simultaneously mixing them. In addition, as necessary, a dispersion treatment can be carried out using a known dispersing machine such as a ball mill, a bead mill, a sand mill, or a roll mill, and/or a stirring treatment can be also carried out using a known stirrer such as a shaking type stirrer.

The composition for forming a magnetic layer can be applied onto, for example, a support. The coating can be carried out using a known coating device such as a blade coater or a die coater. The coating can be carried out by a so-called roll-to-roll method or a batch method.

Examples of the support onto which the composition for forming a magnetic layer is applied include films of various resins such as polyester such as polyethylene terephthalate (PET) and polyethylene naphthalate (PEN), acryls such as polycarbonate (PC) and polymethyl methacrylate (PMMA), cyclic polyolefin, triacetyl cellulose (TAC), polyether sulfide (PES), polyether ketone, and polyimide. For these resin films, reference can be made to paragraphs 0081 to 0086 of JP2015-187260A. As the support, it is possible to use a support in which a surface (a surface to be coated) onto which the composition for forming a magnetic layer is applied is subjected to a peeling treatment according to a known method. One form of the peeling treatment includes forming a release layer. For the release layer, reference can be made to paragraph 0084 of JP2015-187260A. In addition, a commercially available peeling-treated resin film can also be used as the support. In a case of using a support in which the surface to be coated is subjected to the peeling treatment, it is possible to easily separate the magnetic layer and the support after the film formation.

The composition for forming a magnetic layer can also be applied to the surface of the layer described above, such as the metal layer and the resin layer. For example, a partial structure (a “magnetic layer/metal layer” or a “magnetic layer/resin layer”) having a multilayer structure in which a magnetic layer is sandwiched between two metal layers of the electromagnetic wave shielding material can also be produced by applying the composition for forming a magnetic layer to the surface of the metal layer or the resin layer and, as necessary, subjecting the magnetic layer to a pressurization treatment described later. As an example, two partial structures of “magnetic layer/metal layer” are crimped to each other with the magnetic layer sides facing each other by applying pressure and heat, thereby producing an electromagnetic wave shielding material having the layer configuration of the above-described Example A1 “metal layer/magnetic layer/metal layer”.

A coating layer formed by applying the composition for forming a magnetic layer can be subjected to a drying treatment according to a known method such as heating or warm air blowing. The drying treatment can be carried out, for example, under conditions in which the solvent contained in the composition for forming a magnetic layer can be volatilized. As an example, the drying treatment can be carried out for 1 minute to 2 hours in a heated atmosphere having an atmospheric temperature of 80° C. to 150° C.

The alignment degree of the flat-shaped particle described above can be controlled by a solvent kind, solvent amount, liquid viscosity, coating thickness, and the like of the composition for forming a magnetic layer. For example, in a case where the boiling point of the solvent is low, convection occurs due to drying, and thus the value of the alignment degree tends to be large. In a case where the solvent amount is small, the value of the alignment degree tends to increase due to physical interference between adjacent flat-shaped particles. On the other hand, in a case where the liquid viscosity is low, the rotation of flat-shaped particles is more likely to occur, and thus the value of the alignment degree tends to be small. The value of the alignment degree tends to be small as the coating thickness decreases. In addition, carrying out a pressurization treatment described later can contribute to reducing the value of the alignment degree. In a case of adjusting the various manufacturing conditions described above, the alignment degree of the flat-shaped particles can be controlled within the range described above.

### (Pressurization Treatment of Magnetic Layer)

The magnetic layer can also be subjected to a pressurization treatment after film formation. In a case of subjecting the magnetic layer containing the magnetic particles to a pressurization treatment, it is possible to increase the density of the magnetic particles in the magnetic layer, and it is possible to obtain a higher magnetic permeability. In addition, in the magnetic layer containing the flat-shaped particles, it is possible to reduce the value of the alignment degree by the pressurization treatment, and it is possible to obtain a higher magnetic permeability.

The pressurization treatment can be carried out by applying pressure in the thickness direction of the magnetic layer using a plate-shape pressing machine, a roll pressing machine, or the like. In the plate-shape pressing machine, an object to be pressurized can be disposed between two flat press plates that are disposed vertically, and the two press plates can be put together by mechanical or hydraulic pressure to apply pressure to the object to be pressurized. In the roll pressing machine, an object to be pressurized is allowed to pass between the rotating pressurization rolls that are disposed vertically, and at that time, mechanical or hydraulic pressure is applied to the pressurization rolls, or the distance between the pressurization rolls is made to be smaller than the thickness of the object to be pressurized, whereby the pressure can be applied.

The pressure during the pressurization treatment can be set freely. For example, in a case of a plate-shape pressing machine, it is, for example, 1 to 50 newtons (N)/mm². In a case of a roll pressing machine, it is, for example, 20 to 400 N/mm in terms of the linear pressure.

The pressurization time can be set freely. It takes, for example, 5 seconds to 30 minutes in a case where a plate-shape pressing machine is used. In a case where a roll pressing machine is used, the pressurization time can be controlled by the transport speed of the object to be pressurized, where the transport speed is, for example, 10 cm/min to 200 m/min.

The materials of the press plate and the pressurization roll can be randomly selected from metal, ceramics, plastic, and rubber.

In the pressurization treatment, it is also possible to carry out a pressurization treatment by applying a temperature to both of upper and lower press plates of a plate-shape pressing machine or one press plate thereof, or one roll of upper and lower rolls of a roll pressing machine. The magnetic layer can be softened by heating, which makes it possible to obtain a high compression effect in a case where pressure is applied. The temperature at the time of heating can be set freely, and it is, for example, 50° C. or higher and 200° C. or lower. The temperature at the time of heating can be the internal temperature of the press plate or the roll. Such a temperature can be measured with a thermometer installed inside the press plate or the roll.

After the heating and pressurization treatment with the plate-shape pressing machine, the press plates can be spaced apart from each other, for example, in a state where the temperature of the press plates is high, whereby the magnetic layer can be taken out. Alternatively, the press plate can be cooled by a method such as water cooling or air cooling while maintaining the pressure, and then the press plates can be spaced apart to take out the magnetic layer.

In the roll pressing machine, the magnetic layer can be cooled immediately after pressing, by a method such as water cooling or air cooling.

It is also possible to repeat the pressurization treatment two or more times.

In a case where the magnetic layer is formed into a film on a release film, it is possible to carry out a pressurization treatment, for example, in a state where the magnetic layer is laminated on the release film. Alternatively, the magnetic layer can also be peeled off from the release film and can be subjected to a pressurization treatment as a single layer of the magnetic layer.

### (Bonding of Various Layers)

A pressure-sensitive adhesive layer or an adhesive layer can be used for bonding various layers. The pressure-sensitive adhesive layer and the adhesive layer are as described above.

In addition, in the electromagnetic wave shielding material, two layers adjacent to each other can be also adhered to each other, for example, by applying pressure and heat to carry out crimping. A plate-shape pressing machine, a roll pressing machine, or the like can be used for the crimping. For example, in a case where the magnetic layer is disposed as a layer that is in direct contact with the adjacent layer, the magnetic layer is softened in a crimping step, and the contact with the surface of the adjacent layer is promoted, whereby the magnetic layer and the adjacent layer can be bonded to each other without interposing another layer. The pressure at the time of crimping can be set freely. It is, for example, 1 to 50 N/mm² in a case of a plate-shape pressing machine. In a case of a roll pressing machine, it is, for example, 20 to 400 N/mm in terms of the linear pressure. The pressurization time at the time of crimping can be set freely. It takes, for example, 5 seconds to 30 minutes in a case where a plate-shape pressing machine is used. In a case where a roll pressing machine is used, the pressurization time can be controlled by a transport speed of an object to be pressurized, and the transport speed is, for example, 10 cm/min to 200 m/min. The temperature at the time of crimping can be selected freely, and it is, for example, 20° C. or higher and 200° C. or lower. The temperature at the time of crimping can be, for example, the internal temperature of the press plate or the roll.

The electromagnetic wave shielding material can be incorporated into, in any shape, an electronic component or an electronic apparatus. The electromagnetic wave shielding material can have a sheet shape, where the size thereof is not particularly limited. In the present invention and the present specification, the “sheet” has the same meaning as the “film”. In addition, the electromagnetic wave shielding material can be a three-dimensionally formed article obtained by three-dimensionally forming a sheet-shaped electromagnetic wave shielding material, or it can also be a sheet-shaped electromagnetic wave shielding material for three-dimensional forming. As a three-dimensional forming method, it is possible to use various forming methods such as mold press forming, vacuum forming, and air pressure forming. Regarding the forming method, the forming that is carried out without heating a forming target and/or a mold or carried out by heating a forming target and/or a mold without raising the temperature too much is generally called cold forming. In one form, the electromagnetic wave shielding material can exhibit excellent formability in cold forming, and is suitable for cold forming such as draw forming and bulge forming. The draw forming is a forming method in which a sheet-shaped forming target is pressed using a pair of molds of a female die and a male die, thereby being formed into bottomed containers having various shapes such as a cylinder, a square cylinder, and a conical shape. In contrast, a method of forming a formed article having a shape in which a curved surface protrudes from a flat surface, from a sheet-shaped forming target is bulge forming. The bulge forming can be carried out by pressing with only a male die without a female die. The draw forming is roughly classified into deep draw forming and shallow draw forming. A formed article having a shallow depth is formed by the shallow draw forming, and a formed article having a deep depth (for example, having a depth that is deeper than a diameter of a cylinder or a cone, or a length of one side of a pyramid) is formed by the deep draw forming. The electromagnetic wave shielding material can be an electromagnetic wave shielding material that is difficult to be broken in a case of being formed by such a three-dimensional forming method. Known techniques can be applied to the three-dimensional forming method.

In addition, one aspect of the present invention relates to an electromagnetic wave shielding material including:
a magnetic layer containing magnetic particles and a resin, provided between two metal layers,
in which the magnetic layer contains one or more compounds selected from the group consisting of a compound represented by Formula 1 and a compound represented by Formula 2.

In addition, one aspect of the present invention relates to an electromagnetic wave shielding material including:
one or more layers containing
   a resin, and
one or more compounds selected from the group consisting of a compound represented by Formula 1 and a compound represented by Formula 2.

The layer can be one or more layers selected from the group consisting of the magnetic layer, the pressure-sensitive adhesive layer, the adhesive layer, and the resin layer.

The compound selected from the group consisting of a compound represented by Formula 1 and a compound represented by Formula 2 can contribute to improving adhesiveness between two layers in the electromagnetic wave shielding material. In addition, the compound selected from the group consisting of a compound represented by Formula 1 and a compound represented by Formula 2 (preferably, the compound represented by Formula 1) can contribute to improving formability of the electromagnetic wave shielding material.

For the electromagnetic wave shielding material according to any one of the above-described aspects, details thereof can be referred to the above description.

### [Electronic Component]

One aspect of the present invention relates to an electronic component including the electromagnetic wave shielding material. Examples of the electronic component include an electronic component included in an electronic apparatus such as a mobile phone, a mobile information terminal, and a medical device, and various electronic components such as a semiconductor element, a capacitor, a coil, and a cable. The electromagnetic wave shielding material is three-dimensionally formed into any shape, for example, according to the shape of the electronic component, thereby capable of being disposed in the inside of the electronic component, or it is three-dimensionally formed into a shape of a cover material, thereby capable of being disposed as a cover material that covers the outside of the electronic component. Alternatively, it can be three-dimensionally formed into a tubular shape, thereby being disposed as a cover material that covers the outside of the cable.

### [Electronic Apparatus]

One aspect of the present invention relates to an electronic apparatus including the electromagnetic wave shielding material. Examples of the electronic apparatus include electronic apparatuses such as a mobile phone, a mobile information terminal, and a medical device, electronic apparatuses including various electronic components such as a semiconductor element, a capacitor, a coil, and a cable, and electronic apparatuses in which electronic components are mounted on a circuit board. Such an electronic apparatus can include the electromagnetic wave shielding material as a constitutional member of an electronic component included in the device. In addition, as a constitutional member of the electronic apparatus, the electromagnetic wave shielding material can be disposed in the inside of the electronic apparatus or can be disposed as a cover material that covers the outside of the electronic apparatus. Alternatively, it can be three-dimensionally formed into a tubular shape, thereby being disposed as a cover material that covers the outside of the cable.

Examples of the usage form of the electromagnetic wave shielding material include a usage form in which a semiconductor package on a printed board is coated with an electromagnetic wave shielding material. For example, “Electromagnetic wave shielding technology in a semiconductor package” (Toshiba Review Vol. 67, No. 2 (2012) P. 8) discloses a method of obtaining a high shielding effect by electrically connecting a side via of an end part of a package substrate and an inner surface of an electromagnetic wave shielding material in a case where a semiconductor package is coated with an electromagnetic wave shielding material, thereby carrying out ground wiring. In order to carry out such wiring, it is desirable that the outermost layer of the electromagnetic wave shielding material on the electronic component side is a metal layer. In a case where one or both of the outermost layers of the electromagnetic wave shielding material is a metal layer in the electromagnetic wave shielding material, the electromagnetic wave shielding material can be suitably used in a case of carrying out the wiring as described above.

### EXAMPLES

Hereinafter, the present invention will be described in more detail with reference to Examples. However, the present invention is not limited to the embodiments shown in Examples. The term “part” described below is “part by mass”.

### [Resin of Magnetic Layer]

Regarding the resin of the magnetic layer shown in Table 1, “Acrylic resin 1” is acrylic rubber manufactured by Zeon Corporation under the trade name Nipol (model No. AR71). Acrylic resin 1 is an acrylic resin (concentration of solid contents of 100% by mass) synthesized by using ethyl acrylate as a (meth)acrylate compound and using vinyl chloroacetate as a compound represented by Formula 3.

“Acrylic resin 2” is acrylic rubber manufactured by Zeon Corporation under the trade name Nipol (model No. AR51). Acrylic resin 2 is an acrylic resin (concentration of solid contents of 100% by mass) synthesized by using ethyl acrylate as a (meth)acrylate compound and using allyl glycidyl ether as a compound represented by Formula 3.

“Acrylic resin 3”, “Acrylic resin 4”, “Acrylic resin 5”, and “Acrylic resin 6” are acrylic resins synthesized by the following method.

Except that “15 parts of ethyl acrylate, 55 parts of n-butyl acrylate, 28 parts of methoxyethyl acrylate, and 2 parts of mono-n-butyl fumarate” described in paragraph 0097 of JP2022-140567A were changed as follows, emulsion polymerization and formation of the slurry were performed according to the synthesis examples described in the same paragraph. The obtained slurry was dried under reduced pressure in a reduced pressure dryer having an internal atmospheric temperature of 80° C. to obtain an acrylic resin (concentration of solid contents of 100% by mass).

Acrylic resin 3: 97 parts of butyl acrylate and 3 parts of vinyl chloroacetate

Acrylic resin 4: 50 parts of ethyl acrylate, 47 parts of hexyl methacrylate, and 3 parts of vinyl chloroacetate

Acrylic resin 5: 97 parts of octyl acrylate and 3 parts of vinyl chloroacetate

Acrylic resin 6: 97 parts of hexyl methacrylate and 3 parts of vinyl chloroacetate

The number of carbon atoms in the alkyl group of the alkyl (meth)acrylate structure of Acrylic resins 1 to 6 is the value shown in Table 1. Acrylic resin 4 has an alkyl (meth)acrylate structure in which the number of carbon atoms in an alkyl group is 2 and an alkyl (meth)acrylate structure in which the number of carbon atoms in an alkyl group is 6, and thus is denoted by “2/6” in Table 1.

The “urethane resin” is UR-8300 (concentration of solid contents of 30% by mass) manufactured by TOYOBO Co., Ltd.

### [Crosslinking Agent of Magnetic Layer]

Regarding the crosslinking agent of the magnetic layer shown in Table 1, “KBM-903” is a silane coupling agent (trade name: KBM-903) manufactured by Shin-Etsu Silicones Co., Ltd.

“C12DA” is a diamine monomer (1,12-dodecanediamine) manufactured by Tokyo Chemical Industry Co., Ltd.

“CORONATE L” is a polyisocyanate (trade name: CORONATE L) manufactured by Tosoh Corporation.

### Example 1

### <Preparation of Composition for Forming Magnetic Layer (Coating Liquid)>

To a plastic bottle, the following substances were added and mixed with a shaking type stirrer for 96 hours to prepare a coating liquid (composition for forming a magnetic layer);
Fe—Si—Al flat-shaped magnetic particles (Sendust MFS-SUH manufactured by MKT): 9.88 g,
Acrylic resin (see Table 1): 2.42 g,
Crosslinking agent (see Table 1): 0.0495 g, and
Methyl ethyl ketone: 29 g.

In the magnetic layer formed from the prepared coating liquid, the content of the acrylic resin and the content of the crosslinking agent with the total mass of the magnetic layer as 100 parts by mass are the values shown in Table 1.

### <Production of Magnetic Layer>

### (Formation of Film of Magnetic Layer)

A coating liquid was applied onto a peeling surface of a peeling-treated PET film (PET75-LS2 manufactured by NIPPA Co., Ltd.) with a blade coater having a coating gap of 650 μm and dried for 8 minutes in a drying device having an internal atmospheric temperature of 90° C. to form a film of a film-shaped magnetic layer on the peeling-treated PET film.

### (Pressurization Treatment of Magnetic Layer)

Upper and lower press plates of a plate-shape pressing machine (Mini Test Press, manufactured by Toyo Seiki Seisaku-sho, Ltd.) were heated to 140° C. (internal temperature of press plate), and a magnetic layer obtained by peeling off the peeling-treated PET film was sandwiched between two sheets of Teflon (registered trademark) having a thickness of 1 mm and held for 10 minutes in a state where a pressure of 30 N/mm² was applied. The upper and lower press plates were cooled to 50° C. (the internal temperature of the press plates) while maintaining the pressure, and then the magnetic layer was taken out from between the two Teflon (registered trademark) sheets.

A measurement specimen was cut out from the magnetic layer obtained above, and used for various evaluations of the magnetic layer described later. Meanwhile, a measurement specimen for various evaluations of the magnetic layer can also be collected from the electromagnetic wave shielding material by a known method.

### <Production of Electromagnetic Wave Shielding Material>

The magnetic layer cut out from the magnetic layer obtained above was used for producing the electromagnetic wave shielding material. Using an aluminum foil (JIS H4160: 2006 standard, alloy number: 1N30, temper designation: (1)O, Al content: 99.3% by mass or more) having a thickness of 50 μm as the metal layer, three layers of “aluminum foil (metal layer)/magnetic layer/aluminum foil (metal layer)” were laminated to produce a laminate, without interposing other layers between two layers adjacent to each other.

Upper and lower press plates of a plate-shape pressing machine (a large-scale hot press TA-200-1 W manufactured by YAMAMOTO ENG. WORKS CO., LTD.) were heated to 140° C. (the internal temperature of the press plate), and the laminate was installed in the center of the press plate and held for 15 minutes in a state where a pressure of 4.66 N/mm² was applied, whereby the aluminum foil and the magnetic layer were subjected to the thermal compression bonding. The upper and lower press plates were cooled to 50° C. (the internal temperature of the press plates) while maintaining the pressure, and then the laminate was taken out from the plate-shape pressing machine.

In this way, the electromagnetic wave shielding material having a layer configuration of “aluminum foil (metal layer)/magnetic layer/aluminum foil (metal layer)” was obtained.

### [Evaluation Method]

### <Measurement of Magnetic Permeability Before and After Thermal Aging at 120° C.>

A measurement specimen having a size of 28 mm×10 mm was cut out from the magnetic layer, the magnetic permeability was measured using a magnetic permeability measuring apparatus (PER01 manufactured by KEYCOM Corporation), and the magnetic permeability was determined as the real part (μ′) of the complex specific magnetic permeability at a frequency of 3 MHz (measurement temperature: 25° C.). The magnetic permeability obtained in this way is defined as a “magnetic permeability before thermal aging at 120° C.”.

After the measurement specimen after measuring the magnetic permeability before thermal aging at 120° C. was disposed in a high temperature atmosphere of 120° C. for 24 hours, the magnetic permeability was determined by the above method (measurement temperature: 25° C.). The magnetic permeability obtained in this way is defined as a “magnetic permeability after thermal aging at 120° C.”.

Table 2 shows evaluation results obtained by evaluating “magnetic permeability before thermal aging at 120° C.” and “magnetic permeability after thermal aging at 120° C.” according to the following evaluation standards.
A: The magnetic permeability μ′ is 100 or more.
B: The magnetic permeability μ′ is 40 or more and less than 100.
C: The magnetic permeability μ′ is less than 40.

### <Measurement of Electrical Conductivity>

A cylindrical main electrode having a diameter of 30 mm was connected to the negative electrode side of a digital super-insulation resistance meter (TR-811A manufactured by Takeda RIKEN Industries), a ring electrode having an inner diameter of 40 mm and an outer diameter of 50 mm was connected to the positive electrode side thereof, the main electrode was installed on a sample piece of the magnetic layer cut to a size 60 mm×60 mm, the ring electrode was installed at a position surrounding the main electrode, a voltage of 25 V was applied to both electrodes, and the surface electrical resistivity of the magnetic layer alone was measured. The electrical conductivity of the magnetic layer was calculated from the surface electrical resistivity and the following expression. The calculated electrical conductivity was 1.1×10⁻² S/m.

As the thickness, the thickness of the magnetic layer, which had been determined according to the following method, was used.

$$Electrical conductivity [ S / m ] = 1 / ( surface electrical resistivity [ Ω ] \times thickness [ m ] )$$

### <Acquisition of Cross-Sectional Image of Electromagnetic Wave Shielding Material>

Cross-section processing was carried out to expose the cross-section of the electromagnetic wave shielding material by the following method.

An electromagnetic wave shielding material cut out to a size of 3 mm×3 mm was embedded in a resin, and a cross section of the electromagnetic wave shielding material was cut out with an ion milling device (IM4000PLUS manufactured by Hitachi High-Tech Corporation).

The cross-section of the electromagnetic wave shielding material, which had been exposed in this way, was observed with a scanning electron microscope (SU8220, manufactured by Hitachi High-Tech Corporation) under the conditions of an acceleration voltage of 2 kV and a magnification of 100 times to obtain a backscattered electron image. From the obtained image, the thickness of the magnetic layer and the thickness of each of the two metal layers were measured at five points, respectively, with the scale bar as a reference. The respective arithmetic averages were denoted as the thickness of the magnetic layer and the thickness of each of the metal layers. The thickness of the magnetic layer was 30 m, and the thickness of each of the metal layers was 50 m.

### <Acquisition of Cross-Sectional Image of Magnetic Layer>

In a cross section of the electromagnetic wave shielding material, which had been exposed by the cross-section processing in the same manner as described above, a portion of the magnetic layer was observed with a scanning electron microscope (SU8220, manufactured by Hitachi High-Tech Corporation) under the conditions of an acceleration voltage of 2 kV and a magnification of 1,000 times, thereby obtaining a backscattered electron image.

### <Measurement of Aspect Ratio of Magnetic Particle and Alignment Degree of Flat-Shaped Particle>

Using the backscattered electron image acquired as above, the aspect ratio of the magnetic particles was determined according to the method described above, and the flat-shaped particles were specified from the value of the aspect ratio. As a result of determining, as described above, whether or not the magnetic layer contained flat-shaped particles as the magnetic particles, it was determined that the magnetic layer contains flat-shaped particles. Further, as a result of determining the alignment degree of the magnetic particles specified as the flat-shaped particles, according to the method described above, the alignment degree was 13°. In addition, an average value (arithmetic average) of the aspect ratios of all the particles specified as the flat-shaped particles was determined as the aspect ratio of the flat-shaped particles contained in the magnetic layer. The determined aspect ratio was 0.071.

### <Measuring Method of Cross-Linking Degree of Magnetic Layer>

A measurement specimen for the TG/DTA measurement and a measurement specimen for obtaining the mass of the solvent-insoluble component were cut out from the magnetic layer.

For the measurement specimen for TG/DTA measurement, the proportion (unit: % by mass) of the binder component was obtained by the method described above. Specifically, 3 mg of a measurement specimen cut out from the magnetic layer was placed in an alumina pan, and the measurement was performed under a nitrogen atmosphere under conditions of a measurement temperature range of 23° C. to 600° C. and a temperature rising rate of 10° C./min using a TG/DTA 7300 manufactured by Hitachi High-Tech Science Corporation as a TG/DTA measuring apparatus, and the mass reduction % at 600° C. was defined as the proportion (unit: % by mass) of the binder component.

The mass of the solvent-insoluble component was obtained by the method described above using 70 mg of a measurement specimen cut out from the magnetic layer.

Using the values of the mass of the solvent-insoluble component and the proportion of the binder component, which were obtained in this way, the cross-linking degree was calculated according to the above-described expression.

For example, in Example 1, since the mass reduction % at 600° C. was 20%, the proportion of the binder component of the magnetic layer was set to 20%. Therefore, the mass of the binder component of the measurement specimen was calculated as 70 mg×0.2=14 mg. Since the mass of the solvent-insoluble component was 68.6 mg, the cross-linking degree was calculated as follows.

$$Cross - linking degree = [ 1 - \{ ( 70 - 68.6 ) / 70 \times 0.2 \} ] \times 100 = ( 1 - 0.1 ) \times 100 = 90 ( \% )$$

### <Measuring Method of Glass Transition Temperature Tg of Magnetic Layer>

A measurement specimen was cut out from the magnetic layer. For the cut-out measurement specimen, the heat flow measurement was performed under the following conditions using DSC6200 manufactured by SII Crystal Technology Inc. as a differential scanning calorimeter. A temperature raising and lowering cycle was carried out twice for the same specimen, and the second measurement result (2nd-heating) was adopted to determine the glass transition temperature Tg.

### (Measurement Conditions)

Atmosphere in measurement room: Nitrogen (50 mL/min)
Temperature rising rate: 10° C./min
Measurement start temperature: −100° C.
Measurement end temperature: 200° C.
Specimen pan: aluminum pan
Mass of specimen to be measured: 5 mg
Calculation of glass transition temperature Tg: An intermediate temperature between the descent start point and the descent end point of the DSC chart was defined as Tg.

### <Evaluation of Shielding Ability Before and After Thermal Aging at 120° C. (KEC Method)>

An electromagnetic wave shielding material cut to a size of 15 cm×15 cm was installed between antennas of a KEC method evaluation device including a signal generator, an amplifier, a pair of magnetic field antennas, and a spectrum analyzer, and at a frequency of 100 kHz, a ratio of the intensity of the received signal in a case where the electromagnetic wave shielding material was not present to the intensity of the received signal in a case where the electromagnetic wave shielding material was present was determined and denoted as the shielding ability. The operation was carried out for the magnetic field antenna to obtain the electromagnetic wave shielding ability (magnetic field wave shielding ability). KEC is an abbreviation for Kansai Electronic Industry Development Center. The shielding ability evaluated according to the following evaluation standard from the value thus obtained is defined as “shielding ability before thermal aging at 120° C.”.

After the electromagnetic wave shielding material after measuring the shielding ability before thermal aging at 120° C. was disposed in a high temperature atmosphere of 120° C. for 24 hours, the shielding ability was determined by the above method. The shielding ability evaluated according to the following evaluation standard from the value thus obtained is defined as “shielding ability after thermal aging at 120° C.”.

The obtained evaluation results are shown in Table 2.

### (Evaluation Standards)

A: 20 dB or more
B: 15 dB or more and less than 20 dB
C: less than 15 dB

### <Formability>

Using a mold (manufactured by AMADA CO., LTD.) consisting of a male die and a female die, the electromagnetic wave shielding material of Example 1 was subjected to draw forming in an environment at room temperature (25° C.) without heating to produce a hemispherical three-dimensionally formed article. The presence or absence of breakage in the produced three-dimensionally formed article was visually checked, and from the checking results, the formability was evaluated according to the following evaluation standards.

### (Evaluation Standards)

A: A three-dimensionally formed article having a depth of 4 cm can be formed without breakage by using a hemispherical mold having a depth of 4 cm.

B: A three-dimensionally formed article having a depth of 3 cm can be formed without breakage by using a hemispherical mold having a depth of 3 cm.

Further, in a case where a hemispherical mold having a depth of 4 cm was used, the breakage was observed in the obtained three-dimensionally formed article having a depth of 4 cm, or a three-dimensionally formed article having a depth of 4 cm was not obtained.

C: The breakage is observed in the three-dimensionally formed article having a depth of 2 cm, which is obtained by using a hemispherical mold having a depth of 2 cm.

### Examples 2 to 4 and 6 to 9, and Comparative Examples 1 and 2

An electromagnetic wave shielding material was produced and various evaluations were performed according to the method described for Example 1, except that the items shown in Table 1 were changed as shown in Table 1. In Comparative Example 1, in the magnetic layer formed from the prepared composition for forming a magnetic layer, the solid content of the urethane resin was the value described in the column of the amount of the resin in Table 1 with the total mass of the magnetic layer as 100 parts by mass.

### Example 5

An electromagnetic wave shielding material was produced and various evaluations were carried out according to the method described for Example 1, except for the following points.

Alpet 50-50 manufactured by PANAC Co., Ltd. (a laminate in which an aluminum foil (metal layer having an Al content of 99.0% by mass or more) having a thickness of 50 μm and a polyester film (resin layer) having a thickness of 50 μm were bonded to each other by interposing an adhesive layer having a thickness of 3 μm interposed therebetween) was used instead of the aluminum foil. The obtained electromagnetic wave shielding material has a layer configuration of “aluminum foil (metal layer)/adhesive layer/resin layer/magnetic layer/resin layer/adhesive layer/aluminum foil (metal layer)”.

### Example 10

An electromagnetic wave shielding material was produced and various evaluations were performed according to the method described for Example 1, except that the composition for forming a magnetic layer (coating liquid) was prepared as follows.

### <Preparation of Composition for Forming Magnetic Layer (Coating Liquid)>

To a plastic bottle, the following substances were added and mixed with a shaking type stirrer for 96 hours to prepare a coating liquid (composition for forming a magnetic layer);
Fe—Si—Al flat-shaped magnetic particles (Sendust MFS-SUH manufactured by MKT): 20.0 g,
Acrylic resin (see Table 1): 4.84 g,
Crosslinking agent (see Table 1): 0.100 g,
Compound represented by Formula 1 (STARFINE F-10 manufactured by Nissan Chemical Corporation): 0.100 g, and
Methyl ethyl ketone: 57.9 g.

The STARFINE F-10 manufactured by Nissan Chemical Corporation is a cyanuric acid-zinc complex, and R¹, R², and R³ in Formula 1 represent hydrogen atoms.

### Example 11

A composition for forming a magnetic layer (coating liquid) was prepared by the method described for Example 10, except that the STARFINE F-10 manufactured by Nissan Chemical Corporation was changed to VD-5 manufactured by SHIKOKU CHEMICALS CORPORATION, which is a compound represented by Formula 2. An electromagnetic wave shielding material was produced and various evaluations were carried out according to the method described for Example 1, except for the above points.

The VD-5 manufactured by SHIKOKU CHEMICALS CORPORATION is a compound in which two of R⁴, R⁵, and R⁶ in Formula 2 represent an amino group (—NH₂), and the other one represents a 3-triethoxysilylpropylamino group (—NH—(CH₂)₃—Si(OCH₂CH₃)₃).

TABLE 1

| | Magnetic layer | | | | | | |
|---|---|---|---|---|---|---|---|
| | | Number of carbon | Amount of resin | | Amount of crosslinking | | |
| | | atoms in alkyl | (parts by mass | | agent | Cross- | |
| | | group of alkyl | with respect | Cross- | (parts by mass with | linking | |
| | | (meth)acrylate | to total mass of | linking | respect to total mass of | degree | Tg |
| | Resin | structure | magnetic layer) | agent | magnetic layer) | (%) | (° C.) |
| Example 1 | Acrylic resin 1 | 2 | 19.60 | KBM-903 | 0.40 | 90 | −20 |
| Example 2 | Acrylic resin 2 | 2 | 19.60 | C12DA | 0.40 | 81 | −20 |
| Example 3 | Acrylic resin 3 | 4 | 19.60 | KBM-903 | 0.40 | 82 | −40 |
| Example 4 | Acrylic resin 4 | 2/6 | 19.60 | KBM-903 | 0.40 | 70 | −6 |
| Example 5 | Acrylic resin 1 | 22 | 19.60 | KBM-903 | 0.40 | 90 | −20 |
| Example 6 | Acrylic resin 5 | 8 | 19.60 | KBM-903 | 0.40 | 60 | −75 |
| Example 7 | Acrylic resin 6 | 6 | 19.60 | KBM-903 | 0.40 | 60 | 2 |
| Example 8 | Acrylic resin 3 | 4 | 19.95 | KBM-903 | 0.05 | 23 | −40 |
| Example 9 | Acrylic resin 1 | 2 | 19.40 | KBM-903 | 0.60 | 96 | −20 |
| Example 10 | Acrylic resin 1 | 2 | 19.33 | KBM-903 | 0.40 | 88 | −20 |
| Comparative | Urethane resin | 2 | 19.33 | KBM-903 | 0.40 | 90 | −20 |
| Example 1 | | — | 10.20 | CORONATE L | 0.34 | 19 | 23 |
| Comparative | Acrylic resin 1 | 2 | 20.00 | None | — | 0 | −15 |
| Example 2 | | | | | | | |

TABLE 2

| | | | | | Shielding ability | |
|---|---|---|---|---|---|---|
| | Magnetic permeability μ′ | | | | (100 khz) | |
| | Before | After | | | Before | After |
| | thermal | thermal | | | thermal | thermal |
| | aging at | aging at | | Form- | aging at | aging at |
| | 120° C. | 120° C. | Layer configuration of electromagnetic wave shielding material | ability | 120° C. | 120° C. |
| Example 1 | A | A | Metal layer/magnetic layer/metal layer | A | A | A |
| Example 2 | A | A | Metal layer magnetic layer metal layer | A | A | A |
| Example 3 | A | A | Metal layer/magnetic layer/metal layer | A | A | A |
| Example 4 | A | A | Metal layer/magnetic layer/metal layer | A | A | A |
| Example 5 | A | A | Metal layer/adhesive layer/resin layer magnetic | A | A | A |
| | | | layer/resin layer/adhesive layer/metal layer | | | |
| Example 6 | A | B | Metal layer/magnetic layer/metal laver | A | A | B |
| Example 7 | A | A | Metal layer/magnetic layer/metal layer | B | A | A |
| Example 8 | A | B | Metal layer/magnetic layer/metal layer | A | A | B |
| Example 9 | A | A | Metal layer/magnetic layer/metal layer | A | A | A |
| Example 10 | A | A | Metal layer/magnetic layer/metal layer | A | A | A |
| Example 11 | A | A | Metal layer magnetic layer metal layer | A | A | A |
| Comparative | A | C | Metal layer/magnetic layer/metal layer | C | A | C |
| Example 1 | | | | | | |
| Comparative | A | C | Metal layer/magnetic layer/metal layer | A | A | C |
| Example 2 | | | | | | |

From the results shown in Table 2, it can be confirmed that the electromagnetic wave shielding materials of Examples 1 to 11 have excellent heat resistance and excellent formability.

### Example 12

A composition for forming a magnetic layer (coating liquid) was prepared by the method described for Example 10.

Two aluminum foils having a thickness of 50 μm (in accordance with the JIS H4160: 2006 standard, alloy number: 1N30, temper designation: (1)O, Al content: 99.3% by mass or more) were prepared.

A coating liquid was applied onto one surface of each of the two aluminum foils with a blade coater having a coating gap of 300 μm and dried for 8 minutes in a drying device having an internal atmospheric temperature of 90° C. to form a film of a film-shaped magnetic layer on each of the two aluminum foils.

As a result, two partial structures (magnetic layer/metal layer) having a multilayer structure in which the magnetic layer was sandwiched between the two metal layers were produced.

The two produced partial structures were laminated with the magnetic layer sides facing each other to produce a laminate.

Upper and lower press plates of a plate-shape pressing machine (a large-scale hot press TA-200-1 W manufactured by YAMAMOTO ENG. WORKS CO., LTD.) were heated to 140° C. (the internal temperature of the press plate), and the laminate was installed in the center of the press plate and held for 15 minutes in a state where a pressure of 4.66 N/mm² was applied, whereby the two partial structures were subjected to the thermal compression bonding. The upper and lower press plates were cooled to 50° C. (the internal temperature of the press plates) while maintaining the pressure, and then the laminate was taken out from the plate-shape pressing machine.

In this way, the electromagnetic wave shielding material having a layer configuration of “aluminum foil (metal layer)/magnetic layer/aluminum foil (metal layer)” was obtained.

By the method described above for the electromagnetic wave shielding material of Example 1, the thickness of the magnetic layer and the thickness of each of the two metal layers were measured at five points, respectively. The respective arithmetic averages were denoted as the thickness of the magnetic layer and the thickness of each of the metal layers. The thickness of the magnetic layer was 30 m, and the thickness of each of the metal layers was 50 m.

### [Evaluation Method]

### <Peel Strength>

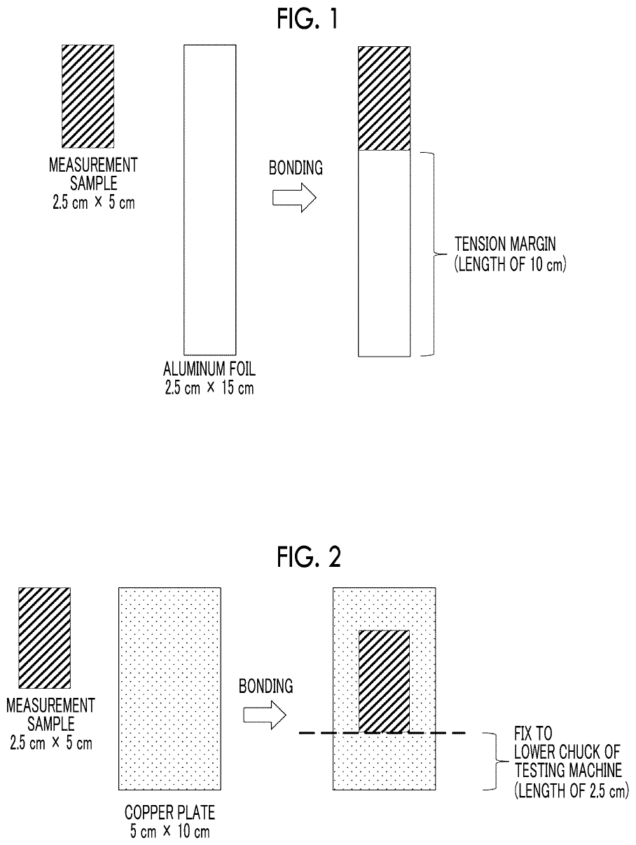

FIGS. 1 and 2 are explanatory views related to a measurement of peel strength.

The peel strength of each of the electromagnetic wave shielding materials of Examples 1 and 10 to 12 was measured by the following method.

A measurement sample having a short side length of 2.5 cm and a long side length of 5 cm was cut out from the electromagnetic wave shielding material of Example 1.

An aluminum foil for test (also simply referred to as “aluminum foil”) (manufactured by TAKEUCHI METAL FOIL & POWDER Co., LTD., model number: A1N30H-O, thickness: 50 μm) having a short side length of 2.5 cm and a long side length of 15 cm was prepared.

The metal layer (aluminum foil) of one outermost layer of the measurement sample and the aluminum foil for test were bonded to each other using an instant adhesive such that one short side of each of foils overlaps one another, thereby producing a tension margin. Such a tension margin is a portion of the aluminum foil for test, which has a length of 10 cm to which the measurement sample is not bonded (see FIG. 1).

Thereafter, a metal layer (aluminum foil) and a copper plate (manufactured by Hikari Co., Ltd., size: thickness of 1 mm, short side length of 5 cm, long side length of 10 cm) of the other outermost layer of the measurement sample (that is, the side on which the tension margin was not produced) were bonded using double-sided tape (see FIG. 2) by disposing the measurement sample on the center portion of the copper plate.

A portion of the copper plate to which the electromagnetic wave shielding material was not attached was fixed to a lower chuck of a testing machine (see FIG. 2).

Thereafter, the tension margin was folded at 1800 and fixed to an upper chuck of the testing machine, and a peel test was performed under the following measurement conditions. Table 3 shows the peel strength calculated by dividing the load (unit: N (Newton)) obtained as a measured value by the short side length (2.5 cm).

The peel strength measured by the above-described method can be said to be an indicator of an adhesive force between two layers adjacent to each other in the laminate, and it can be said that the higher the value of the peel strength measured by the above-described method, the higher the adhesive force between the adjacent metal layer and the magnetic layer in the electromagnetic wave shielding material. From the viewpoint of high adhesiveness between the adjacent metal layer and the magnetic layer, the peel strength measured by the above method is preferably more than 0.5 N/cm, more preferably 0.6 N/cm or more, still more preferably 1.0 N/cm or more, 1.5 N/cm or more, 2.0 N/cm or more, 2.5 N/cm or more, 3.0 N/cm or more, 3.5 N/cm or more, 4.0 N/cm or more, and 4.5 N/cm or more in this order. Such peel strength can be, for example, 8.0 N/cm or less, 7.5 N/cm or less, or 7.0 N/cm or less.

### (Measurement Conditions)

Testing machine: a universal material testing instrument TENSILON (RTF-1310) manufactured by A&D Company, Limited.
Measurement environment: temperature of 23° C., relative humidity of 50%
Load cell: 500 newtons (N)
Tensile rate: 30 mm/min

### <Evaluation of Durability (Drop Peeling Test)>

Each of the electromagnetic wave shielding materials of Examples 1 and 10 to 12 was subjected to a drop peeling test according to the Du Pont method described in JIS-K-5600-5-3: 1999. A drop test was performed 5 times at a height of 200 mm under the conditions of a radius of 6.35 mm for the mold and the support and a mass of 300 g for the weight, and the evaluation was performed according to the following standards. The expression “the drop test was carried out five times” means that the drop test was carried out once for each of five measurement samples cut out from the electromagnetic wave shielding material of each of Examples (and thus the number of times of the test was a total of five times).

A: No peeling was observed in all of the five tests.

B: peeling was observed at least once between the adjacent metal layer and the magnetic layer in the five tests.

C: In the 5 tests, peeling was observed between the adjacent metal layer and the magnetic layer in all of the 5 tests.

The above results are shown in Table 3. In a case where the electromagnetic wave shielding material of Example 12 was evaluated for “shielding ability before thermal aging at 120° C.” and “shielding ability after thermal aging at 120° C.” by the method described for Example 1, the evaluation results of both were “A”.

TABLE 3

| | Electromagnetic wave shielding material | | |
|---|---|---|---|
| | | Peel | Drop |
| | | strength | peeling |
| | Layer configuration | (N/cm) | test |
| Example 1 | Metal layer/magnetic layer/metal layer | 2.0 | C |
| Example 10 | Metal layer/magnetic layer/metal layer | 5.0 | A |
| Example 11 | Metal layer/magnetic layer/metal layer | 3.0 | B |
| Example 12 | Metal layer/magnetic layer/metal layer | 7.0 | A |

From the results shown in Table 3, it can be confirmed that the electromagnetic wave shielding materials of Examples 10 to 12 that contain the compound represented by Formula 1 or the compound represented by Formula 2 in the metal layer have more excellent adhesiveness between the two layers of the magnetic layer and the metal layer, as compared with the electromagnetic wave shielding material of Example 1.

One aspect of the present invention is useful in the technical fields of various electronic components and various electronic apparatuses.

What is claimed is:

1. An electromagnetic wave shielding material comprising:
a magnetic layer containing magnetic particles and an acrylic resin, provided between two metal layers,
wherein a cross-linking degree of the magnetic layer is 20% or more, and
a glass transition temperature Tg of the magnetic layer is −80° C. or higher.

2. The electromagnetic wave shielding material according to claim 1,
wherein the glass transition temperature Tg of the magnetic layer is −80° C. or higher and lower than 5° C.

3. The electromagnetic wave shielding material according to claim 1,
wherein the magnetic layer contains a compound represented by Formula 1: 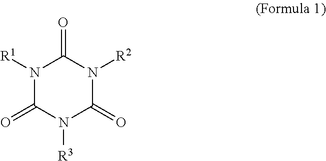
in Formula 1, R¹, R², and R³ each independently represent a hydrogen atom, an allyl group, an organic group including a hydroxy group, an organic group including a carboxy group, an organic group including an alkoxysilyl group, or a glycidyl group.

4. The electromagnetic wave shielding material according to claim 3,
wherein the glass transition temperature Tg of the magnetic layer is −80° C. or higher and lower than 5° C.

5. The electromagnetic wave shielding material according to claim 1,
wherein the magnetic layer contains a compound represented by Formula 2: 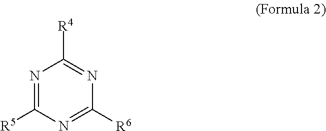
in Formula 2, R⁴, R⁵, and R⁶ each independently represent an amino group or an organic group including an alkoxysilyl group.

6. The electromagnetic wave shielding material according to claim 5,
wherein the glass transition temperature Tg of the magnetic layer is −80° C. or higher and lower than 5° C.

7. The electromagnetic wave shielding material according to claim 1,
wherein the magnetic layer contains an acrylic resin having an alkyl (meth)acrylate structure in which the number of carbon atoms in an alkyl group is 2 or more and 8 or less.

8. The electromagnetic wave shielding material according to claim 1,
wherein the magnetic layer contains an acrylic resin having an alkyl (meth)acrylate structure in which the number of carbon atoms in an alkyl group is 2 or more and 4 or less.

9. The electromagnetic wave shielding material according to claim 1,
wherein the cross-linking degree of the magnetic layer is 20% or more and 98% or less.

10. The electromagnetic wave shielding material according to claim 1, further comprising:
one or more layers containing a resin, provided between the magnetic layer sandwiched between the two metal layers and one or both of the two metal layers.

11. The electromagnetic wave shielding material according to claim 1,
wherein one or more of the metal layers are metal layers having an Al content of 80.0% by mass or more.

12. The electromagnetic wave shielding material according to claim 1,
wherein the glass transition temperature Tg of the magnetic layer is −40° C. or higher and lower than −5° C.

13. The electromagnetic wave shielding material according to claim 1,
wherein the magnetic layer contains an acrylic resin having an alkyl (meth)acrylate structure in which the number of carbon atoms in an alkyl group is 2 or more and 4 or less,
the cross-linking degree of the magnetic layer is 20% or more and 98% or less,
one or more of the metal layers are metal layers having an Al content of 80.0% by mass or more, and
the glass transition temperature Tg of the magnetic layer is −40° C. or higher and lower than −5° C.

14. The electromagnetic wave shielding material according to claim 13, further comprising:
one or more layers containing a resin, provided between the magnetic layer sandwiched between the two metal layers and one or both of the two metal layers.

15. The electromagnetic wave shielding material according to claim 13,
wherein the magnetic layer contains a compound represented by Formula 1: 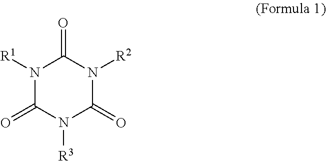
in Formula 1, R¹, R², and R³ each independently represent a hydrogen atom, an allyl group, an organic group including a hydroxy group, an organic group including a carboxy group, an organic group including an alkoxysilyl group, or a glycidyl group.

16. The electromagnetic wave shielding material according to claim 13,
wherein the magnetic layer contains a compound represented by Formula 2: 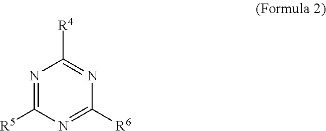
in Formula 2, R⁴, R⁵, and R⁶ each independently represent an amino group or an organic group including an alkoxysilyl group.

17. An electronic component comprising:
the electromagnetic wave shielding material according to claim 1.

18. An electronic apparatus comprising:
the electromagnetic wave shielding material according to claim 1.
